(19) United States
(12) Patent Application Publication
(10) Pub. No.: US 2026/0031152 A1
(43) Pub. Date: Jan. 29, 2026

(54) NAND MEMORY ARRAY BIASING FOR MATRIX VECTOR MULTIPLICATION

(71) Applicant: Micron Technology, Inc., Boise, ID (US)

(72) Inventors: Hernan Castro, Shingle Springs, CA (US); Huai-Yuan Tseng, San Ramon, CA (US)

(21) Appl. No.: 19/245,100

(22) Filed: Jun. 20, 2025

Related U.S. Application Data
(60) Provisional application No. 63/674,726, filed on Jul. 23, 2024.

(51) Int. Cl. G11C 16/10; G11C 16/04; G11C 16/08; G11C 16/26

(52) U.S. Cl. CPC G11C 16/102; G11C 16/0483; G11C 16/08; G11C 16/26

(57) ABSTRACT

Systems, methods, and apparatus for memory devices that apply a fixed gate bias to memory cells during programming and multiplication. In one approach, a fixed voltage bias is applied to gates of the memory cells when the cells are programmed. Output currents from the memory cells are measured to control the extent of the programming. A target output current is used for determining when to end programming and corresponds to a weight to be stored. After programming, inputs are applied to the memory cells, and output currents from the memory cells are accumulated to perform matrix vector multiplication.

### RELATED APPLICATIONS

The present application claims priority to Prov. U.S. Pat. App. Ser. No. 63/674,726 filed Jul. 23, 2024, the entire disclosure of which application is hereby incorporated herein by reference.

### FIELD OF THE TECHNOLOGY

At least some embodiments disclosed herein relate to memory devices in general and more particularly, but not limited to, memory devices that use memory cells for performing multiplication and other operations.

### BACKGROUND

Limited memory bandwidth is a significant problem in machine learning systems. For example, DRAM devices used in current systems store large amounts of weights and activations used in deep neural networks (DNNs).

In one example, deep learning machines, such as those supporting processing for convolutional neural networks (CNNs), perform processing to determine a huge number of calculations per second. For example, input/output data, deep learning network training parameters, and intermediate results are constantly fetched from and stored in one or more memory devices (e.g., DRAM). A DRAM type of memory is typically used due to its cost advantages when large storage densities are involved (e.g., storage densities greater than 100 MB). In one example of a deep learning hardware system, a computational unit (e.g., a system-on-chip (SOC), FPGA, CPU, or GPU) is attached to a memory device(s) (e.g., a DRAM device).

Existing computer architectures use processor chips specialized for serial processing and DRAMs optimized for high density memory. The interface between these two devices is a major bottleneck that introduces latency and bandwidth limitations and adds a considerable overhead in power consumption. Memory on-chip is area expensive and it is not possible to add large amounts of memory to the CPU and GPU processors currently used to train and deploy DNNs.

Memory in neural networks is used to store input data, weight parameters and activations as an input propagates through the network. In training, activations from a forward pass must be retained until they can be used to calculate the error gradients in the backwards pass. As an example, a network can have 26 million weight parameters and compute 16 million activations in a forward pass. If a 32-bit floating-point value is used to store each weight and activation, this corresponds to a total storage requirement of 168 MB.

GPUs and other machines need significant memory for the weights and activations of a neural network. GPUs cannot efficiently execute directly the small convolutions used in deep neural networks, so they need significant activation or weight storage. Finally, memory is also required to store input data, temporary values and program instructions. For example, a high performance GPU may need over 7 GB of local DRAM.

Large amounts of storage data cannot be kept on the GPU processor. In many cases, high performance GPU processors may have only 1 KB of memory associated with each of the processor cores that can be read fast enough to saturate the floating-point data path. Thus, at each layer of a DNN, the GPU needs to save the state to external DRAM, load up the next layer of the network, and then reload the data. As a result, the off-chip memory interface suffers the burden of constantly reloading weights and saving and retrieving activations. This significantly slows down training time and increases power consumption.

In one example, images and other sensors are used and generate large amounts of data. It is inefficient to transmit certain types of data from the sensors to general-purpose microprocessors (e.g., central processing units (CPU)) for processing in some applications. For example, it is inefficient to transmit image data from image sensors to microprocessors for image segmentation, object recognition, feature extraction, etc.

Some image processing can include intensive computations involving multiplications of columns or matrices of elements for accumulation. Some specialized circuits have been developed for the acceleration of multiplication and accumulation operations. For example, a multiplier-accumulator (MAC unit) can be implemented using a set of parallel computing logic circuits to achieve a computation performance higher than general-purpose microprocessors.

### BRIEF DESCRIPTION OF THE DRAWINGS

The embodiments are illustrated by way of example and not limitation in the figures of the accompanying drawings in which references indicate similar elements.

FIG. 1 shows an integrated circuit device having sensors, a memory cell array, and circuits to perform inference computations according to one embodiment.

FIG. 2 shows the computation of a column of weight bits multiplied by a column of input bits to provide an accumulation result according to one embodiment.

FIG. 3 shows a method of computation in an integrated circuit device based on summing output currents from memory cells according to one embodiment.

FIG. 4 shows an analog weight-stationary architecture for matrix vector multiplication (MVM) according to one embodiment.

FIG. 5 shows an analog weight-stationary approach using a select gate drain (SGD)-cell architecture according to one embodiment.

FIG. 6 shows an exemplary arrangement of memory cells for a tile of a NAND flash memory array according to one embodiment.

FIG. 7 shows sensing circuitry coupled to a bitline used to access NAND flash memory cells according to one embodiment.

FIG. 8 shows strings of memory cells connected to a common bitline segment according to one embodiment.

FIG. 9 shows exemplary target currents on an I-V curve of a memory cell with each target current corresponding to a different weight value.

FIG. 10 shows a bitline used to access multi-pillar memory cells of a memory array according to one embodiment.

FIG. 11 shows a top view of bitlines used to access single pillar memory cells.

FIG. 12 shows a top view of bitlines used to access multi-pillar memory cells according to one embodiment.

FIG. 13 shows an architecture having resistive random access memory (RRAM) or NOR memory cells arranged in a parallel configuration for performing multiplication according to one embodiment.

FIG. 14 shows a method for forming a memory device having multi-pillar memory cells for use when performing multiplication according to one embodiment.

FIG. 15 shows an exemplary graph of string current vs. gate voltage for a memory cell in a string of cells in a standard NAND memory device.

FIG. 16 shows a memory array having vertical pillars of memory cells according to one embodiment.

FIG. 17 shows a string of memory cells having an active cell to which a gate voltage is applied, and having other non-active cells to which a pass voltage is applied according to one embodiment.

FIG. 18 shows strings of memory cells connected to bitlines used to accumulate output currents from the cells according to one embodiment.

FIG. 19 shows an exemplary graph of string current vs. gate voltage for a memory cell in a string of memory cells in a NAND memory array for which a fixed gate bias is applied to memory cells being used for a multiplication according to one embodiment.

FIG. 20 shows a method for programming memory cells by measuring output currents according to one embodiment.

### DETAILED DESCRIPTION

The following disclosure describes various embodiments for memory devices that use memory cells (e.g., multi-pillar memory cells) to perform multiplication and other operations. Each memory cell provides an output current depending on its prior programming and the input to the memory cell during read inference. In one embodiment, the memory devices apply biases to access lines (e.g., wordlines and/or bitlines) when performing multiplication and/or other operations using a three-dimensional NAND flash memory cell array. The memory device may, for example, store data used by a host device (e.g., a computing device of an autonomous vehicle, or another computing device that accesses data stored in the memory device). In one example, the memory device is a solid-state drive mounted in an electric vehicle.

There can be a combination of various mechanisms that can cause a change in the magnitude of the output current from a memory cell so that it is higher or lower than the desired initial target threshold voltage or current to which the memory cell has been programmed. For example, since an MVM or other operation is a sum of output currents from selected memory cells, any cell/array mechanism that results in a deviation from the intended target current values for the cells can result in an error.

One problem that can cause such an error is IR voltage drop (or simply IR drop) along access lines that results from the output current flows in a memory array. This problem can be particularly acute for currents in bitlines that are used to accumulate output currents from strings of memory cells during MVM. For example, bitlines (BL) accumulate current for an MVM function of a memory device. The voltage on each bitline varies due to IR drops. The IR drops can be a function of bitline resistance, the weight range (e.g., range of target output currents) used to program memory cells, and/or weight and input distribution (e.g., input patterns) during inference reads. The IR drop reduces the target voltage across each string, which introduces error in the MVM function.

The IR drop can be, for example, a function of memory cell location within an array tile, and/or current in the array. The current is a function of both the input to the multiplication and the weight pattern of the memory cells. In one example, one factor that affects IR drop is the location of a memory cell relative to one or more voltage drivers. Bitlines and pillars have some resistance, so the IR drop seen by a cell increases as the cell is located further from the driver(s).

To counter such IR drops, various embodiments described below reduce the effective resistance of the bitlines. By reducing effective IR drops along the bitlines, the window budget can be improved and/or error in the MVM reduced. This window budget is sometimes expressed as an acceptable amount of error. The extent of error that can be tolerated also depends, for example, on the AI model being used.

In one example, a bitline is formed using the top metal for a NAND memory cell array. Output currents from memory cells are accumulated by the bitline for multiplication. Sometimes the accumulated current can be significant if, for example, numerous strings along a bitline are conducting high currents due to the programmed state of memory cells and/or active inputs. This can cause large IR drops and create errors in the multiplication results.

In one embodiment, a memory cell array uses multi-pillar memory cells to reduce IR drops when performing computations for layers of a neural network. For example, these computations include matrix vector multiplication (MVM) for each layer of the neural network. The weights for the neural network are stored in the memory cell array and multiplication using the weights is performed in the memory cell array itself based on output currents from memory cells in the array. The output currents are digitized and used by a controller to support the MVM.

In addition to the above, improved power efficiency is particularly desirable for use of neural networks on mobile devices and automobiles. Storing the weights for a neural network in the memory device and doing the multiplication in the memory device avoids or reduces the need to move the weights to a central processing unit or other processing device. This reduces the power consumption required to move data to and from memory, and also reduces the memory bandwidth problem described herein.

More generally, neural networks are one of the most popular classes of machine learning algorithms (e.g., modeled after our understanding of how the brain works). For example, a network has a large number of neurons that on their own perform fairly simple computations, but together can learn complex and non-linear functions. For example, neuron computation is basically multiplication of multiple input values by neuron weights (which represent how important each input is to the computation), and summing of the results. The weights are learned during network training. Each result is then passed through a non-linear activation function to allow the neuron to learn complex relationships.

In terms of computational burden, the multiplication of all input values by neuron weights for all neurons in the network is the most demanding use of processing power. For example, this multiplication can be 90% or more of the computational requirement, depending on the network design. When scaled to a full layer of the neural network, the computation is vectorized and becomes a matrix vector multiplication problem. The computations are also sometimes referred to as dot product or sum-of-products (SOP) computations.

Deep learning technologies are an exemplary implementation of neural networks and have been playing a significant role in a variety of applications such as image classification, object detection, speech recognition, natural language processing, recommender systems, automatic generation, and robotics etc. Many domain-specific deep learning accelerators (DLA) (e.g., GPU, TPU and embedded NPU), have been introduced to provide the required efficient implementations of deep neural networks (DNN) from cloud to edge. However, the limited memory bandwidth is still a critical challenge due to frequent data movement back and forth between compute units and memory in deep learning, especially for energy constrained systems and applications (e.g., edge Als).

Conventional Von-Neumann computer architecture has developed with processor chips specialized for serial processing and DRAMs optimized for high density memory. The interface between these two devices is a major bottleneck that introduces latency and bandwidth limitations and adds a considerable overhead in power consumption. With the growing demand of higher accuracy and higher speed for AI applications, larger DNN models are developed and implemented with huge amounts of weights and activations. The resulting bottlenecks of memory bandwidth and power consumption on inter-chip data movement are significant technical problems.

Over time, neural networks continue to grow exponentially in complexity, which means there are many more computations required. This stresses the performance of traditional computation architectures. For example, purpose-built compute blocks are needed for the MVM operation to meet performance requirements (GPUs, Digital Accelerators). Also, neuron weights must be fetched from memory, which both causes performance bottlenecks, and is energy inefficient, as mentioned above.

In some cases, the precision of the computations can be reduced to address these concerns. For example, the selection of the type of neural network training can enable roughly equivalent neural network accuracy with significantly lower precision. The lower precision can improve the performance and/or energy efficiency of a neural network implementation. Also, the use of a lower precision can be supportive of storing weights in memory and performing multiplication in the memory, as described herein.

For example, when using lower precision representations of weights and inputs (e.g., using a smaller number of bits for each weight or input), a key aspect to consider is the final answer such as a classification of an image. In many cases, the accuracy in obtaining the correct final answer can be maintained almost the same (e.g., only 2-5% decrease) even when using lower precision if the neural network model is structured properly (e.g., the manner or approach used to train the network). For example, analog multiplication in the memory itself may be even more desirable because of the ability to achieve similar accuracy as in traditional approaches, but with this lower precision.

A neural network design itself typically dictates the size of the MVM operation at every layer of the network. Each layer can have a different number of features and neurons. In one embodiment, the MVM computation will take place in a portion of a NAND flash or other memory array. This portion is represented in the array as tiles.

In one embodiment, a memory device has memory cells configured in an array, with each memory cell programmed, for example, to allow an amount of current to go through when a voltage is applied in a predetermined voltage region to represent a first logic state (e.g., a first value stored in the memory cell), or a negligible amount of current to represent a second logic state (e.g., a second value stored in the memory cell).

The memory device performs computations based on applying voltages in a digital fashion, in the form of whether or not to apply an input voltage to generate currents for summation over a line (e.g., a bitline of a memory array). The total current on the line will be the multiple of the amount of current allowed for cells programmed at the first value. In one example, an analog-to-digital converter is used to convert the current to a digital result of a sum of bit-by-bit multiplications.

As mentioned above, memory cells store weights used in multiplication. The weight is set at a target threshold voltage (VT) to sink a specific amount of current (e.g., a target current magnitude that corresponds to the value of the stored weight). The accuracy of this current needs to be maintained to obtain a proper summed value or result from the multiplication. Thus, the accuracy of the MVM computation depends on stable output currents from the memory cells. It is desired that the output current value is consistent across the numerous varying conditions experienced during the operation of a memory device. Reducing IR drops by using multi-pillar memory cells can improve this output current consistency.

To address the above IR drop, power efficiency, and/or other technical problems, a memory device integrates memory and processing. In one example, memory and inference computation processing are integrated in the same integrated circuit device. In some embodiments, the memory device is an integrated circuit device having an image or other sensor, a memory cell array, and one or more circuits to use the memory cell array to perform inference computation on data from the sensor. In some embodiments, the memory device includes or is used with various types of sensors (e.g., LIDAR, radar, sound).

Existing methods of matrix vector multiplication use digital logic gates. Digital logic implementations are more complex, consume more silicon area, and dissipate more power as compared to various embodiments described below. These embodiments effectively reduce the multiplication to a memory access function which can be parallelized in an array. The accumulation function is carried out by wires that connect these memory elements, which can also be parallelized in an array. By combining these two features in an array, matrix vector multiplication can be performed more efficiently than methods using digital logic gates.

To address the technical problem of maintaining a desired target output current during multiplication or other operations, a memory device reduces IR drops in bitlines by using multi-pillar memory cells. With this approach, the error characteristics of the MVM or other operation can be improved.

In one embodiment, a NAND flash memory device is formed on a semiconductor substrate. A memory array having multi-pillar memory cells extends vertically above the semiconductor substrate, and the memory array includes at least one first pillar of transistors (e.g., a first row of pillars) and at least one second pillar of transistors (e.g., a second row of pillars running parallel to the first row). Each memory cell includes a respective first transistor from the first pillar and a respective second transistor from the second pillar.

A bitline is formed in a metal or other conductive layer overlying the first and second pillars. The bitline is electrically connected to the first and second pillars. The bitline accumulates output currents from memory cells of the first and second pillars when performing multiplication (e.g., MVM).

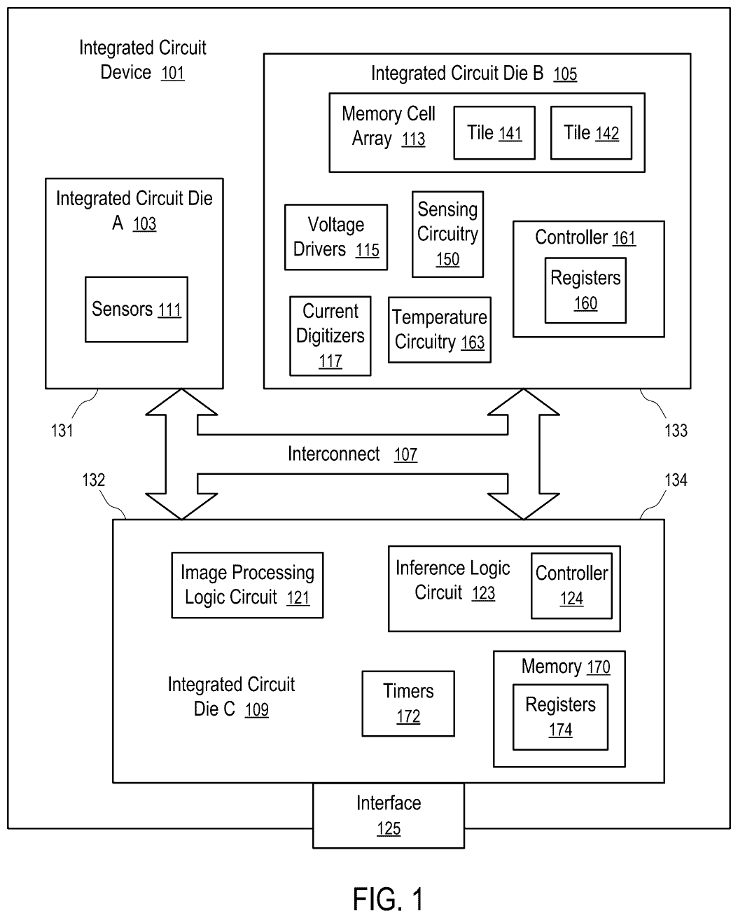

In one embodiment, a NAND analog weight-stationary device is used to perform multiplication. A wordline voltage is applied to gates of multi-pillar memory cells forming one or more synapses of a neural network. In one embodiment, an integrated circuit (IC) device (e.g., 101 of FIG. 1 below) includes a host interface configured to communicate with a host. The IC device includes a memory cell array having memory cells to store weights for a neural network. Access lines (e.g., wordline, bitline) are used to access the memory cells. The IC device also includes logic circuitry to receive, via the host interface from the host, weights for the neural network. The logic circuitry programs a portion of the memory cells of the memory cell array to store the weights.

In one embodiment, an image sensor is configured with an analog capability to support inference computations by using matrix vector multiplication, such as computations of an artificial neural network. The image sensor can be implemented as an integrated circuit device having an image sensor chip and a memory chip. The memory chip can have a 3D memory array configured to support multiplication and accumulation operations. The integrated circuit device includes one or more logic circuits configured to process images from the image sensor chip, and to operate the memory cells in the memory chip to perform multiplications and accumulation operations.

The memory chip can have multiple layers of memory cells. Each memory cell can be programmed to store a bit of a binary representation of an integer weight. Each input line can be applied a voltage according to a bit of an integer. Columns of memory cells can be used to store bits of a weight matrix; and a set of input lines can be used to control voltage drivers to apply read voltages on rows of memory cells according to bits of an input vector.

In one embodiment, the threshold voltage or state of a memory cell used for multiplication and accumulation operations can be programmed such that the current going through the memory cell subjected to a predetermined read voltage is either a predetermined amount representing a value of one stored in the memory cell, or negligible to represent a value of zero stored in the memory cell. When the predetermined read voltage is not applied, the current going through the memory cell is negligible regardless of the value stored in the memory cell. As a result of the configuration, the current going through the memory cell corresponds to the result of a 1-bit weight, as stored in the memory cell, multiplied by a 1-bit input, corresponding to the presence or the absence of the predetermined read voltage driven by a voltage driver controlled by the 1-bit input.

Output currents of the memory cells, representing the results of a column of 1-bit weights stored in the memory cells and multiplied by a column of 1-bit inputs respectively, are connected to a common line for summation. The summed current in the common line is a multiple of the predetermined amount; and the multiples can be digitized and determined using an analog to digital converter or other digitizer. Such results of 1-bit to 1-bit multiplications and accumulations can be performed for different significant bits of weights and different significant bits of inputs. The results for different significant bits can be shifted (e.g., left shifted) to apply the weights of the respective significant bits for summation to obtain the results of multiplications of multi-bit weights and multi-bit inputs with accumulation.

Using the capability of performing multiplication and accumulation operations implemented via memory cell arrays, a logic circuit can be configured to perform inference computations, such as the computation of an artificial neural network.

Various embodiments of memory devices performing multiplication using logical states of memory cells are described below. The memory cells in an array may generally be of various types. Examples include NAND or NOR flash memory cells and phase-change memory (PCM) cells. In one example, the PCM cells are chalcogenide memory cells. In one example, floating gate or charge trap memory devices in NAND or NOR memory configurations are used.

In various embodiments using chalcogenide memory cells, multiplications and other processing is performed by operating the chalcogenide memory cells in a sub-threshold region. This is to avoid thresholding or snapping of any memory cell, which typically would prevent proper multiplication (e.g., due to large undesired output currents associated with snapping).

Summation of results represented by output currents from memory cells can be implemented via connecting the currents to a common line (e.g., a bitline or a source SRC line). The summation of results can be digitized to provide a digital output. In one example, an analog-to-digital converter is used to measure the sum as the multiple of the predetermined amount of current and to provide a digital output.

In one embodiment, a memory device implements unsigned 1-bit to multi-bit multiplication. A multi-bit weight can be implemented via multiple memory cells. Each of the memory cells is configured to store one of the bits of the multi-bit weight, as just described above. A voltage represented by a 1-bit input can be applied to the multiple memory cells separately to obtain results of unsigned 1-bit to 1-bit multiplication as described above.

Each memory cell has a position corresponding to its stored bit in the binary representation of the multi-bit weight. Its digitized output (e.g., from the summing of output currents from memory cells on a common bitline) can be shifted left according to its position in the binary representation to obtain a shifted result. For example, the digitized output of the memory cell storing the least significant bit of the multi-bit weight is shifted by 0 bit; the digitized output of the memory cell storing the second least significant bit of the multi-bit weight is shifted by 1 bit; the digitized output of the memory cell storing the third least significant bit of the multi-bit weight is shifted by 2 bit; etc. The shifted results can be summed to obtain the result of the 1-bit input multiplied by the multi-bit weight stored in the multiple memory cells.

FIG. 1 shows an integrated circuit device 101 having one or more sensors 111, a memory cell array 113, and circuits to perform inference computations according to one embodiment. In FIG. 1, the integrated circuit device 101 has an integrated circuit die 109 having logic circuits 121 and 123, an integrated circuit die 103 having the sensors 111 (e.g., an image sensing pixel array), and an integrated circuit die 105 having the memory cell array 113.

In one example, the integrated circuit die 109 having logic circuits 121 and 123 is a logic chip; the integrated circuit die 103 having the sensors 111 is a sensor chip; and the integrated circuit die 105 having the memory cell array 113 is a memory chip.

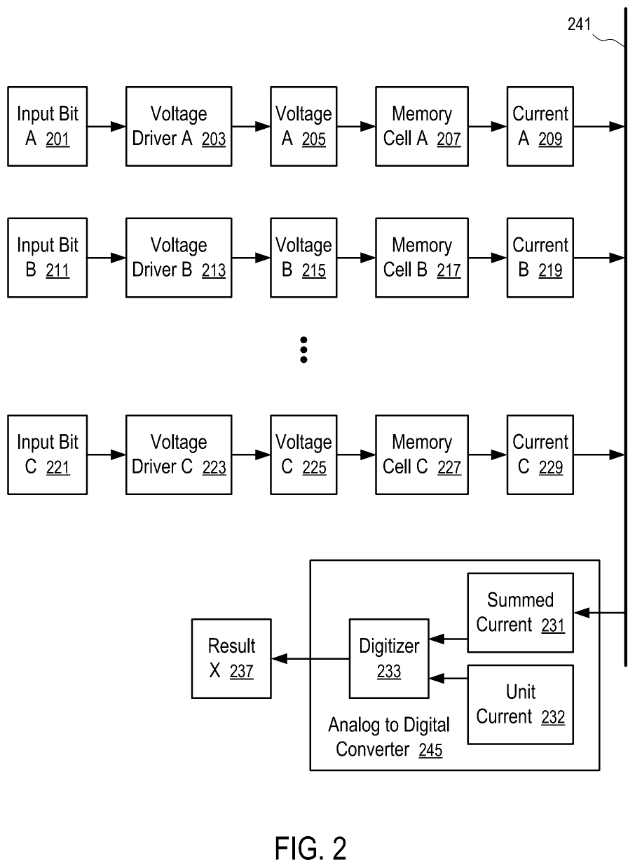

In FIG. 1, the integrated circuit die 105 having the memory cell array 113 further includes voltage drivers 115 and current digitizers 117. The memory cell array 113 is connected such that currents generated by the memory cells in response to voltages applied by the voltage drivers 115 are summed in the array 113 for columns of memory cells (e.g., as illustrated in FIG. 2); and the summed currents are digitized to generate the sum of bit-wise multiplications. The inference logic circuit 123 can be configured to instruct the voltage drivers 115 to apply read voltages according to a column of inputs, and perform shifts and summations to generate the results of a column or matrix of weights multiplied by the column of inputs with accumulation.

In one embodiment, sensing circuitry 150 is coupled to memory cells in tiles 141, 142. Sensing circuitry 150 is used to sense one or more characteristics of the memory cells. In one embodiment, sensing circuitry 150 includes circuitry to precharge bitlines of tiles 141, 142. Sensing circuitry 150 is configured to receive signals from controller 124 and/or read registers 160 to configure sensing operation. In one embodiment, sensing circuitry 150 includes ADCs or other digitizers to convert sums of output currents from memory cells that are accumulated on access lines (e.g., accumulated on bitlines) to provide digital results (e.g., accumulation results).

The inference logic circuit 123 can be further configured to perform inference computations according to weights stored in the memory cell array 113 (e.g., the computation of an artificial neural network) and inputs derived from the data generated by the sensors 111. Optionally, the inference logic circuit 123 can include a programmable processor that can execute a set of instructions to control the inference computation. Alternatively, the inference computation is configured for a particular artificial neural network with certain aspects adjustable via weights stored in the memory cell array 113. Optionally, the inference logic circuit 123 is implemented via an application-specific integrated circuit (ASIC), a field-programmable gate array (FPGA), or a core of a programmable microprocessor.

In one embodiment, inference logic circuit 123 includes controller 124. In one example, controller 124 manages communications with a host system via interface 125. In one example, controller 124 performs signed or unsigned multiplication using memory cell array 113. In one embodiment, controller 124 selects either signed or unsigned multiplication to be performed based on the type of data to be used as an input for the multiplication. In one example, controller 124 selects signed multiplication in response to determining that inputs for the multiplication are signed.

In FIG. 1, the integrated circuit die 105 having the memory cell array 113 has a bottom surface 133; and the integrated circuit die 109 having the inference logic circuit 123 has a portion of a top surface 134. The two surfaces 133 and 134 can be connected via bonding (e.g., using hybrid bonding) to provide a portion of an interconnect 107 between metal portions on the surfaces 133 and 134.

Similarly, the integrated circuit die 103 having the sensors 111 has a bottom surface 131; and the integrated circuit die 109 having the inference logic circuit 123 has another portion of its top surface 132. The two surfaces 131 and 132 can be connected via bonding (e.g., using hybrid bonding) to provide a portion of the interconnect 107 between metal portions on the surfaces 131 and 132.

An image sensing pixel array of sensors 111 can include a light sensitive element configured to generate a signal responsive to intensity of light received in the element. For example, an image sensing pixel implemented using a complementary metal-oxide-semiconductor (CMOS) technique or a charge-coupled device (CCD) technique can be used.

In some implementations, the image processing logic circuit 121 is configured to pre-process an image from the image sensing pixel array to provide a processed image as an input to the inference computation controlled by the inference logic circuit 123. Optionally, the image processing logic circuit 121 can also use the multiplication and accumulation function provided via the memory cell array 113.

In some implementations, interconnect 107 includes wires for writing image data from the image sensing pixel array to a portion of the memory cell array 113 for further processing by the image processing logic circuit 121 or the inference logic circuit 123, or for retrieval via an interface 125. The inference logic circuit 123 can buffer the result of inference computations in a portion of the memory cell array 113.

The interface 125 of the integrated circuit device 101 can be configured to support a memory access protocol, or a storage access protocol or any combination thereof. Thus, an external device (e.g., a processor, a central processing unit) can send commands to the interface 125 to access the storage capacity provided by the memory cell array 113.

For example, the interface 125 can be configured to support a connection and communication protocol on a computer bus, such as a peripheral component interconnect express (PCIe) bus, a serial advanced technology attachment (SATA) bus, a universal serial bus (USB) bus, a compute express link, etc. In some embodiments, the interface 125 can be configured to include an interface of a solid-state drive (SSD), such as a ball grid array (BGA) SSD. In some embodiments, the interface 125 is configured to include an interface of a memory module, such as a double data rate (DDR) memory module, a dual in-line memory module, etc. The interface 125 can be configured to support a communication protocol such as a protocol according to non-volatile memory express (NVMe), non-volatile memory host controller interface specification (NVMHCIS), etc.

The integrated circuit device 101 can appear to be a memory sub-system from the point of view of a device in communication with the interface 125. Through the interface 125, an external device (e.g., a processor, a central processing unit) can access the storage capacity of the memory cell array 113. For example, the external device can store and update weight matrices and instructions for the inference logic circuit 123, retrieve images generated by an image sensing pixel array of sensors 111 and processed by the image processing logic circuit 121, and retrieve results of inference computations controlled by the inference logic circuit 123.

Integrated circuit die 105 includes a local controller 161 having registers 160. Local controller 161 can perform at least a portion of control functions handled by controller 124. Registers 160 can be set by controller 124 and/or a host to configure memory cell programming adjustments.

Integrated circuit die 109 includes memory 170 having registers 174. In one embodiment, configuration data from a host is received via interface 125. In one example, the configuration data is data used to set registers 174 and/or 160 to configure adjustment of memory cell programming based on a context of memory cells of IC device 101. In one example, this context includes a temperature determined using temperature circuitry 163. In one example, temperature circuitry 163 provides temperatures of memory cells in memory cell array 113. In one example, temperature circuitry 163 is embedded within memory cell array 113.

In one example, the context used to adjust cell programming includes currents measured by sensing circuitry 150. In one example, one or more string currents are measured for pillars of NAND flash memory cells.

In one example, the context used to adjust cell programming includes a time that has elapsed since memory cells have been last programmed. One or more timers 172 are used to monitor this time for memory cells in memory cell array 113.

In one example, the context used to adjust cell programming includes data regarding values of weights stored in memory cells of memory cell array 113. In one example, this data indicates a number of memory cells in an erased state.

In one example, the context used to adjust cell programming includes data obtained from one or more sensors 111. Sensors 111 can include a temperature sensor.

In one example, IC device 101 performs processing for a neural network. The processing includes MVM computations mapped to tiles 141, 142.

In FIG. 1, the interface 125 is positioned, for example, at the bottom side of the integrated circuit device 101, while the image sensor chip is positioned at the top side of the integrated device 101 to receive incident light for generating images.

The voltage drivers 115 in FIG. 1 can be controlled to apply voltages to program the threshold voltages of memory cells in the array 113. Data stored in the memory cells can be represented by the levels of the programmed threshold voltages of the memory cells.

In one example, the interface 125 can be operable for a host system to write data into the memory cell array 113 and to read data from the memory cell array 113. For example, the host system can send commands to the interface 125 to write the weight matrices of the artificial neural network into the memory cell array 113 and read the output of the artificial neural network, the raw data from the sensors 111, or the processed image data from the image processing logic circuit 121, or any combination thereof.

The inference logic circuit 123 and/or controller 161 can be programmable and include a programmable processor, an application-specific integrated circuit (ASIC), or a field-programmable gate array (FPGA), or any combination thereof. Instructions for implementing the computations of the artificial neural network can also be written via the interface 125 into the memory cell array 113 for execution by the inference logic circuit 123.

FIG. 2 shows the computation of a column of weight bits multiplied by a column of input bits to provide an accumulation result according to one embodiment. In FIG. 2, a column of memory cells 207, 217, . . . , 227 (e.g., in the memory cell array 113 of an integrated circuit device 101) can be programmed to have threshold voltages at levels representative of weights stored one bit per memory cell.

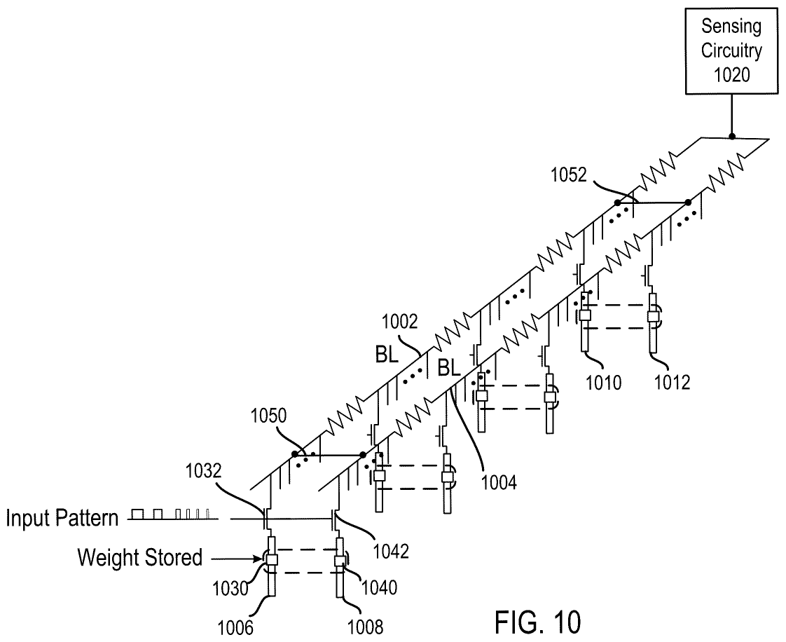

In one embodiment, at least a portion of the memory cells are implemented as multi-pillar memory cells such as shown in FIG. 10.

Voltage drivers 203, 213, . . . , 223 (e.g., in the voltage drivers 115 of an integrated circuit device 101) are configured to apply voltages 205, 215, . . . , 225 to the memory cells 207, 217, . . . , 227 respectively according to their received input bits 201, 211, . . . , 221.

For example, when the input bit 201 has a value of one, the voltage driver 203 applies the predetermined read voltage as the voltage 205, causing the memory cell 207 to output the predetermined amount of current as its output current 209 if the memory cell 207 has a threshold voltage programmed at a lower level, which is lower than the predetermined read voltage, to represent a stored weight of one, or to output a negligible amount of current as its output current 209 if the memory cell 207 has a threshold voltage programmed at a higher level, which is higher than the predetermined read voltage, to represent a stored weight of zero.

However, when the input bit 201 has a value of zero, the voltage driver 203 applies a voltage (e.g., zero) lower than the lower level of threshold voltage as the voltage 205 (e.g., does not apply the predetermined read voltage), causing the memory cell 207 to output a negligible amount of current at its output current 209 regardless of the weight stored in the memory cell 207. Thus, the output current 209 as a multiple of the predetermined amount of current is representative of the result of the weight bit, stored in the memory cell 207, multiplied by the input bit 201.

Similarly, the current 219 going through the memory cell 217 as a multiple of the predetermined amount of current is representative of the result of the weight bit, stored in the memory cell 217, multiplied by the input bit 211; and the current 229 going through the memory cell 227 as a multiple of the predetermined amount of current is representative of the result of the weight bit, stored in the memory cell 227, multiplied by the input bit 221.

The output currents 209, 219, . . . , and 229 of the memory cells 207, 217, . . . 227 are connected to a common line 241 (e.g., a bitline or source line in tile 141) for summation. In one example, common line 241 is a bitline. A constant voltage (e.g., ground or −1 V) is maintained on the bitline when summing the output currents.

The summed current 231 is compared to the unit current 232, which is equal to the predetermined amount of current, by a digitizer 233 of an analog to digital converter 245 to determine the digital result 237 of the column of weight bits, stored in the memory cells 207, 217, . . . , 227 respectively, multiplied by the column of input bits 201, 211, . . . , 221 respectively with the summation of the results of multiplications.

The sum of negligible amounts of currents from memory cells connected to the line 241 is small when compared to the unit current 232 (e.g., the predetermined amount of current). Thus, the presence of the negligible amounts of currents from memory cells does not alter the result 237 and is negligible in the operation of the analog to digital converter 245.

In FIG. 2, the voltages 205, 215, . . . , 225 applied to the memory cells 207, 217, . . . , 227 are representative of digitized input bits 201, 211, . . . , 221; the memory cells 207, 217, . . . , 227 are programmed to store digitized weight bits; and the currents 209, 219, . . . , 229 are representative of digitized results.

The result 237 is an integer that is no larger than the count of memory cells 207, 217, . . . , 227 connected to the line 241. The digitized form of the output currents 209, 219, . . . , 229 can increase the accuracy and reliability of the computation implemented using the memory cells 207, 217, . . . , 227.

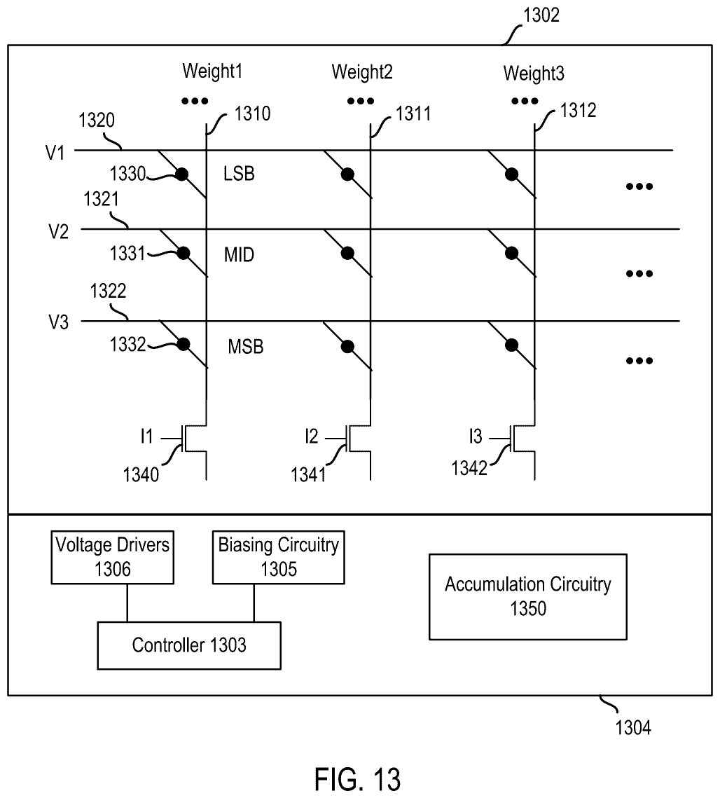

In general, a weight involving a multiplication and accumulation operation can be more than one bit. Memory cells can be used to store the different significant bits of weights (e.g., as illustrated in FIG. 13) to perform multiplication and accumulation operations. The circuit illustrated in FIG. 2 can be considered a multiplier-accumulator unit configured to operate on a column of 1-bit weights and a column of 1-bit inputs. Multiple such circuits can be connected in parallel to implement a multiplier-accumulator unit to operate on a column of multi-bit weights and a column of 1-bit inputs.

The circuit illustrated in FIG. 2 can also be used to read the data stored in the memory cells 207, 217, . . . , 227. For example, sensing circuitry 150 can be used to sense a current associated with a memory cell. For example, to read the data or weight stored in the memory cell 207, the input bits 211, . . . , 221 can be set to zero to cause the memory cells 217, . . . , 227 to output a negligible amount of currents into the line 241 (e.g., as a bitline). The input bit 201 is set to one to cause the voltage driver 203 to apply the predetermined read voltage. Thus, the result 237 from the digitizer 233 provides the data or weight stored in the memory cell 207. Similarly, the data or weight stored in the memory cell 217 can be read via applying one as the input bit 211 and zeros as the remaining input bits in the column; and data or weight stored in the memory cell 227 can be read via applying one as the input bit 221 and zeros as the other input bits in the column.

In general, the circuit illustrated in FIG. 2 can be used to select any of the memory cells 207, 217, . . . , 227 for read or write. A voltage driver (e.g., 203) can apply a programming voltage pulse (e.g., one or more pulses or other waveform, as appropriate for a memory cell type) to adjust the threshold voltage of a respective memory cell (e.g., 207) to erase data, to store data or a weight, etc.

In general, an input involving a multiplication and accumulation operation can be more than 1 bit. For example, columns of input bits can be applied one column at a time to the weights stored in an array of memory cells to obtain the result of a column of weights multiplied by a column of inputs with results accumulated.

The multiplier-accumulator unit illustrated in FIG. 2 can be implemented in integrated circuit device 101 in FIG. 1.

In one implementation, a memory chip (e.g., integrated circuit die 105) includes circuits of voltage drivers, digitizers, shifters, and adders to perform the operations of multiplication and accumulation. The memory chip can further include control logic configured to control the operations of the drivers, digitizers, shifters, and adders to perform the operations as in FIG. 2.

The inference logic circuit 123 can be configured to use the computation capability of the memory chip (e.g., integrated circuit die 105) to perform inference computations of an application, such as the inference computation of an artificial neural network. The inference results can be stored in a portion of the memory cell array 113 for retrieval by an external device via the interface 125 of the integrated circuit device 101.

Optionally, at least a portion of the voltage drivers, the digitizers, the shifters, the adders, and the control logic can be configured in the integrated circuit die 109 for the logic chip.

The memory cells (e.g., memory cells of array 113) can include volatile memory, or non-volatile memory, or both. Examples of non-volatile memory include flash memory, memory units formed based on negative-and (NAND) logic gates, negative-or (NOR) logic gates, phase-change memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two layers of wires running in perpendicular directions, where wires of one layer run in one direction in the layer located above the memory element columns, and wires of the other layer are in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include read-only memory (ROM), programmable read-only memory (PROM), erasable programmable read-only memory (EPROM) and electronically erasable programmable read-only memory (EEPROM) memory, etc. Examples of volatile memory include dynamic random-access memory (DRAM) and static random-access memory (SRAM).

The integrated circuit die 105 and the integrated circuit die 109 can include circuits to address memory cells in the memory cell array 113, such as a row decoder and a column decoder to convert a physical address into control signals to select a portion of the memory cells for read and write. Thus, an external device can send commands to the interface 125 to write weights into the memory cell array 113 and to read results from the memory cell array 113.

In some implementations, the image processing logic circuit 121 can also send commands to the interface 125 to write images into the memory cell array 113 for processing.

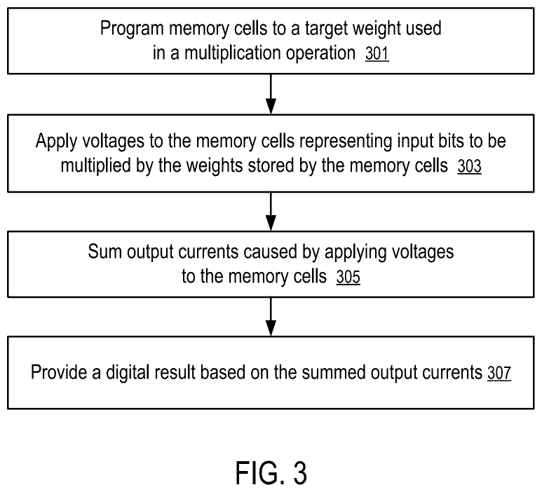

FIG. 3 shows a method of computation in an integrated circuit device based on summing output currents from memory cells according to one embodiment. For example, the method of FIG. 3 can be performed in an integrated circuit device 101 of FIG. 1 using multiplication and accumulation techniques of FIG. 2, 4, or 13.

The method of FIG. 3 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 3 is performed at least in part by one or more processing devices (e.g., a controller 124 of inference logic circuit 123 of FIG. 1, or local controller 161 of integrated circuit die 105).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 301, memory cells (or sets of memory cells such as 4-cell sets storing a bit of a signed weight) are programmed to a target weight for performing multiplication. In one example, memory cells of memory cell array 113 are programmed. In one example, memory cells 207, 206, 208 are programmed to store weights of different bit significance. The weights correspond to a multi-bit weight (e.g., Weight1 of FIG. 13). In one example, the memory cells are multi-pillar memory cells of FIG. 10.

At block 303, voltages are applied to the memory cells. The voltages represent input bits to be multiplied by the weights stored by the memory cells. In one example, voltage drivers apply input voltages 205, 215, 225.

At block 305, output currents from the memory cells caused by applying the voltages are summed. In one example, the output currents are collected and summed using line 241 as in FIG. 2.

At block 307, a digital result based on the summed output currents is provided. In one example, the summed output currents are used to generate Result X 237 of FIG. 2.

In one embodiment, the device further comprises an interface (e.g., 125) operable for a host system to write data into the memory cell array and to read data from the memory cell array.

In one embodiment, the memory cells include first and second memory cells; the respective weight stored by the first memory cell is a most significant bit (MSB) of a multi-bit weight; and the respective weight stored by the second memory cell is a least significant bit (LSB) of the multi-bit weight.

In one embodiment, the digitizer is configured in an analog-to-digital converter.

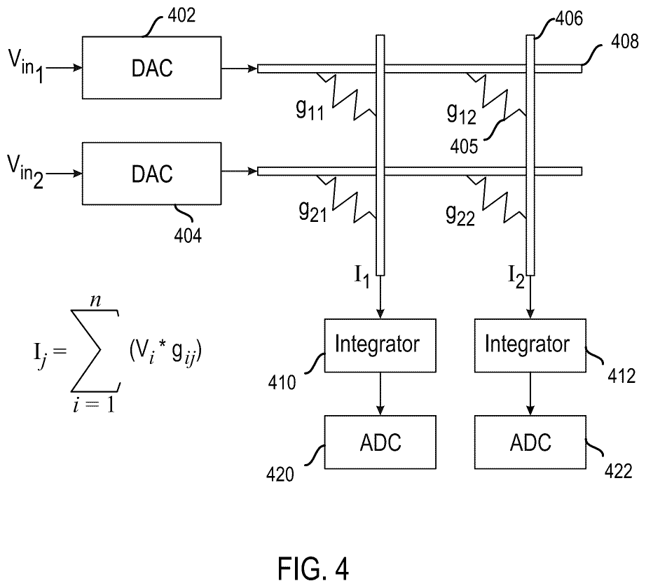

FIG. 4 shows an analog weight-stationary architecture for matrix vector multiplication (MVM) according to one embodiment. Because the computational burden is largely on the MVM operation when executing a neural network, an analog weight-stationary architecture is used that focuses on the MVM operation. The other computations/logic required can generally be implemented in the digital and/or analog space since their impact on performance and energy efficiency is relatively small.

In a weight-stationary architecture, the computation is performed where the weights are stored (e.g., performed in a NAND flash memory device that stores weights). This removes or reduces the performance bottleneck and power inefficiency of moving the weights out of memory for the computation. The MVM computation is performed in the analog domain. This typically results in some computational error that does not exist in the digital domain.

The weights are stored in storage units 405 (e.g., memory cells) within the memory device (e.g., 101). The input is sent to an electrode 408 of the storage unit, resulting in a multiplication of the input and the weight (conductance of storage unit based on the stored weight) (e.g., weight of g12 multiplied by input Vin₁). Digital-to-analog converters (DAC) 402, 404 convert digital inputs into magnitudes for analog voltages used to drive electrodes 408 (e.g., an access line such as a select gate drain line).

The result is summed to another electrode (e.g., 406) (e.g., a common line 241 of FIG. 2) within the memory array and detected by an ADC 420, 422. For example, integrators 410, 412 accumulate currents I₁, I₂ from memory cells 405 determined by the conductances of the cells and provide the accumulated currents as inputs to ADC 420, 422.

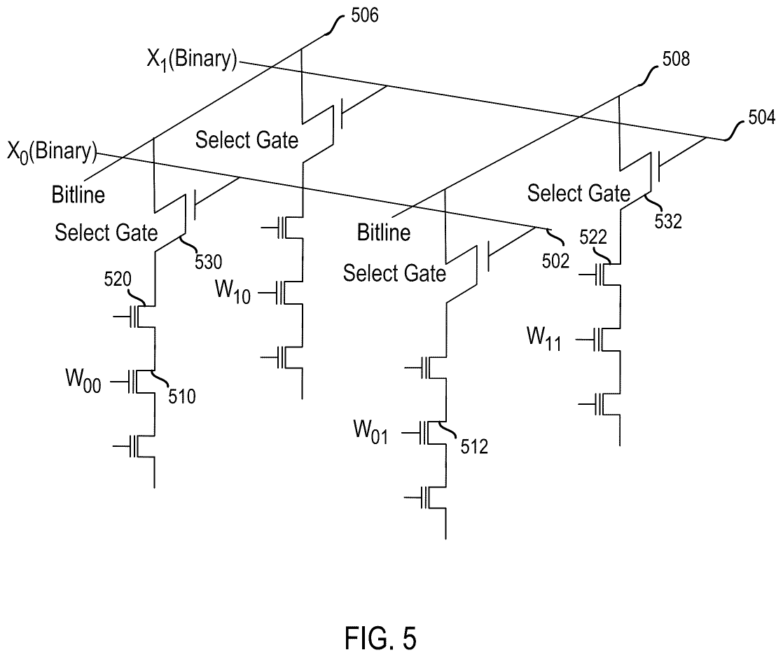

FIG. 5 shows an exemplary architecture that can be used to perform MVM on weights stored within memory cells of a three-dimensional (3D) NAND flash memory device according to one embodiment. The memory cells extend vertically upwards from a semiconductor substrate (not shown). The memory cells are arranged as vertical pillars (sometimes referred to as strings) of cells. The cells in each pillar/string are connected in series. Bypass voltages (e.g., Vpass) are applied to the gates of non-selected memory cells during multiplication.

The threshold voltage (VT) of a memory cell is set (programmed) based on the intended weight. When the cell is read with a wordline voltage, the cell will sink some current (based on the cell I-V characteristics) as a function of the weight stored within the cell. The VT of the memory cell is adjusted during programming based on the context of the memory cell as determined by the controller (e.g., 124 and/or 161) (e.g., as described above).

An input to multiply by a weight can be introduced to a pillar in various ways. For example, the input is applied as a gate voltage of another cell with a fixed threshold (VT). For example, a select gate is used as a digital input (e.g., by applying a digital time-sliced pulse stream). For example, the input is applied on a bitline.

In one example, the summation of multiplication results is done by summing currents at the bitline. In one example, the summation of multiplication results is done by summing currents at the source. This approach requires unique source routes, which are not part of a traditional 3D NAND architecture.

More specifically, FIG. 5 shows an analog weight-stationary approach using a select gate drain (SGD)-cell architecture according to one embodiment. For example, each weight (e.g., unsigned or signed bit) is stored in one cell or a set of cells (e.g., 510, 512) with a wordline (WL) voltage (e.g., W00, W01, W10, W11) applied to each selected cell. An input is applied on a select gate drain (SGD) line 502, 504 (e.g., as a digital time-sliced pulse stream). Select transistors 530, 532 connect each pillar to a bitline 506, 508. Output currents are summed on bitlines 506, 508. Bypass voltages are applied to non-selected cells 520, 522 during the multiplication.

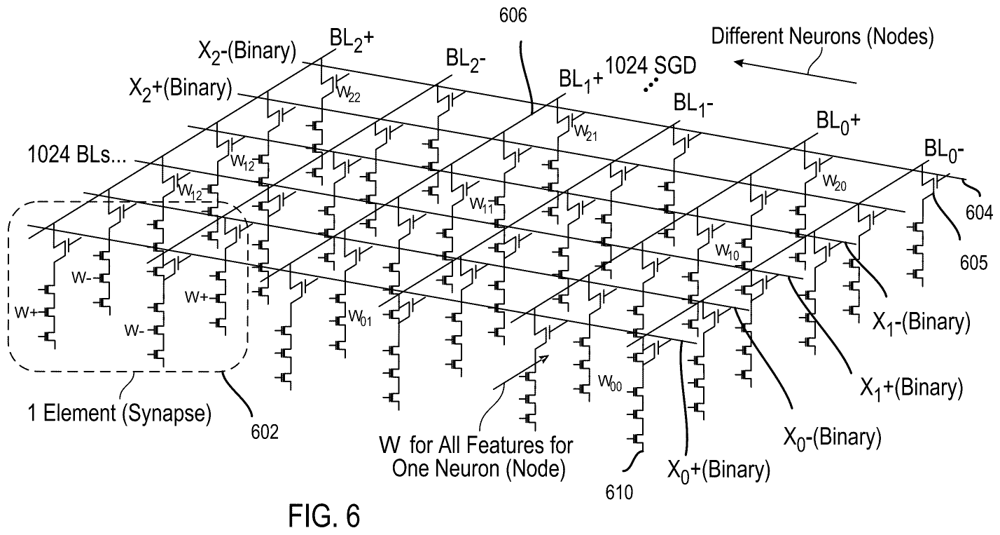

Various memory cell implementations can be used for performing signed multiplication (e.g., using the array of FIG. 6 below). In one embodiment, the signed multiplication is performed in a so-called four-quadrant system, in which each of an input and a weight to be multiplied can have a positive or negative sign. For example, some neural network models make use of matrix vector multiplication in which the weights of the model are signed. In one example, resistive random-access memory (RRAM) cells are used. In one example, NAND or NOR flash memory cells are used.

In one embodiment, matrix vector multiplication is performed using stored weights. Input signals are multiplied by the weights to provide a result. In one example, the weights are determined by training a neural network model. The model uses both positive and negative values for the weights. In one example, the weights are stored in memory cells of memory cell array 113 of FIG. 1. In one example, the model is trained using image data, and the trained model provides inference results based on inputs from an image sensor.

In one example, the result has been determined in response to a request from a host system over interface 125 of FIG. 1. In one example, the signed inputs used to produce the result are based on data collected by sensors 111 of FIG. 1.

In one example, the input lines provide voltages to a memory cell set. The set has four memory cells. In one example, the input lines can be wordlines, bitlines, or select gate lines (SL or SGD), depending on type of memory cell and the particular set configuration (e.g., memory cells arranged in series as for NAND flash versus memory cells arranged in parallel as for RRAM or NOR).

In one embodiment, an image is provided as an input to a neural network. The neural network includes convolution layers. The size of each layer varies. For example, each layer has a different number of features and neurons. The neural network provides a result. In one example, the result is a classification of an object represented by the image.

When performing computations, matrix vector multiplication operations are mapped to tiles in a memory cell array (e.g., 113). For example, this mapping involves identifying portions of the memory cell array that are to be used during the computation for a particular layer. This mapping typically varies as computations progress from one layer to another.

In one example, the image is data obtained from an image sensing pixel array of sensors 111. In one example, weights for the neural network have been programmed into memory cells of tiles 141, 142.

FIG. 6 shows an exemplary arrangement of memory cells for a tile of a NAND flash memory array according to one embodiment. The NAND flash memory array is an example of memory cell array 113. The tile is an example of tile 141, 142. The memory cells are arranged in vertical strings 610 (e.g., extending above a semiconductor substrate (not shown)).

The illustrated tile has a size of, for example, 512 features and 512 neurons. The tile has 1,024 bitlines and 1,024 select gate drain (SGD) lines because the tiles are configured to store signed weights for each of the 512 neurons. For example, set 602 includes four selected memory cells (indicated by W+, W−) that store a bit of a signed weight (e.g., an LSB bit or a MSB bit).

Inputs for multiplication are provided on select gate lines 604. The select gate lines are used to turn select transistors (e.g., 605) on or off depending on the value of the input. For example, each bit position of an input feature vector (X0, X1, X2, etc.) is run serially. Each Xn is the same bit position of each of the 512 features. Output currents from the selected memory cells are accumulated on bitlines (e.g., 606).

In one embodiment, a memory device includes tiles organized in a memory cell array (e.g., 113). In one example, the array includes about 1,500 NAND tiles. The tiles are filled (programmed) with weights for neurons to be used. The particular weights that are valid for a given MVM computation will vary.

Each tile includes neurons and features. In one example, each of the neurons corresponds to a bitline or a source line used to accumulate output currents for memory cells. In one example, each of the features corresponds to a select gate drain line used to provide one or more input bits for multiplication of weights stored in the memory cells.

In preparation for a matrix vector multiplication operation, a controller causes voltage biases to be applied to various access lines of a tile. These access lines can include the bitlines or source lines, and/or the select gate drain lines. These access lines can further include wordlines and/or other lines of the memory cell array. In one embodiment, the bias applied to one or more of the foregoing access lines is varied based on the context determined for a memory cell and/or memory cell array. The bias adjustment can be different for each type of access line, and/or for individual access lines.

In one embodiment, the bitlines are electrically shorted (e.g., connected by one or more shunts as shown in FIG. 10 or 12) so that each memory cell can use a transistor from two or more pillars. For example, the bitlines can be shorted so that pairs of single bitlines can operate as a single logical bitline for the multi-pillar memory cells.

In one embodiment, bitlines are pre-charged and used during the multiplication operation. In one embodiment, each bitline is connected to an analog-to-digital converter (ADC). Each ADC will be charged and used during the multiplication operation. In one embodiment, the bitlines are pre-charged using an adjustment based on the context of the memory cell array (e.g., as described above).

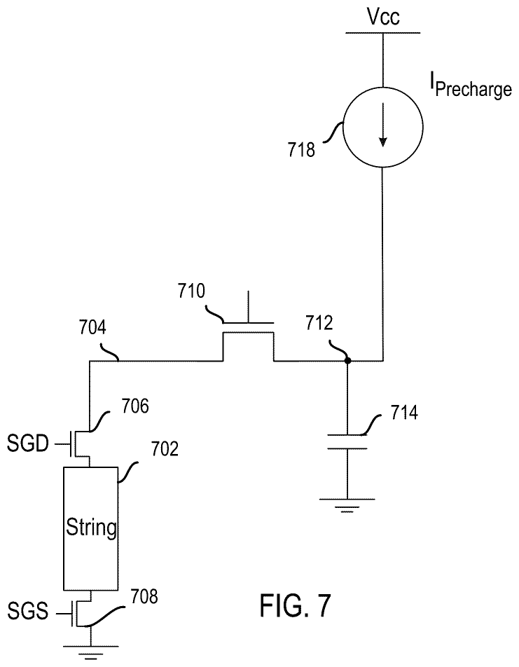

FIG. 7 shows sensing circuitry (e.g., using a sensing amplifier or other sensing circuit) coupled to a bitline 704 used to access NAND flash memory cells according to one embodiment. The sensing circuitry may include an ADC. The memory cells are located in string 702. Select gate drain and source transistors 706, 708 are used to control access to string 702. Select gate transistor 706 is coupled to bitline 704.

The sensing circuitry includes a current source 718 used to pre-charge bitline 704 in preparation for sensing a current (e.g., accumulated output currents) and/or a state of a selected memory cell in string 702. The sensing circuitry is connected to bitline 704 by transistor 710.

During sensing, node 712 is charged, which corresponds to a capacitance 714 (e.g., parasitic capacitance of the sensing circuitry). Bitline 704 is also charged.

In one embodiment, a memory device uses a memory cell array organized as sets of memory cells. In one example, resistive random-access memory (RRAM) cells are used. In one example, NAND or NOR flash memory cells are used.

Each set is programmable to store a multi-bit signed weight. After being programmed, voltage drivers apply voltages (based on adjustment of the voltages using the context of the memory cells) to the memory cells in each set. The voltages represent multi-bit signed inputs to be multiplied by the multi-bit signed weights.

One or more common lines are coupled to each set. The lines receive one or more output currents from the memory cells in each set (e.g., similarly as discussed above for sets of two or four cells). Each common line accumulates the currents to sum the output currents from the sets.

In one example, the line(s) are bitline(s) extending vertically above a semiconductor substrate. As an example, 512 memory cell sets are coupled to the line(s). Inputs are provided using 512 pairs of select lines (e.g., SL+, SL−), with one pair used per set. The output currents from each of the 512 sets are collected on the line(s), and then one or more total current magnitudes are digitized to provide first and second digital values.

In one example, the memory device includes one or more digitizers. The digitizer(s) provide signed results (e.g., as described above) based on summing the output currents from each of the 512 sets on first and second common lines.

A first digital value (e.g., an integer) representing the current on the first common line is determined as the multiple of a predetermined current (e.g., as described above) representing 1. A second digital value representing the current on the second common line is determined as the multiple of the predetermined current. The first and second digital values are, for example, outputs from a digitizer(s).

In one embodiment, a memory device includes a memory cell array having sets of NAND flash memory cells (e.g., using the array of FIG. 6). Each set is programmable to store a multi-bit signed weight. Voltage drivers apply voltages to each set. The voltages correspond to a multi-bit signed input, which is multiplied by the multi-bit signed weight for each set. Two common lines are coupled to each set. Each common line sums a respective output current from each set. A digitizer on each common line provides signed results based on summing the output currents from the sets. Each signed result corresponds to a bit significance of the input and a bit significance of the weight, for example as described above. The signed results are added together taking respective bit significance into consideration to provide first and second digital values that represent a signed accumulation result from the multi-bit to multi-bit multiplication.

In one embodiment, a signed input is applied to a set of memory cells on two wires (e.g., two select lines), each wire carrying a signal. Whether the input is positive or negative depends on where the magnitude of the signal is provided. In other words, the sign depends on which wire carries the signal. The other wire carries a signal of constant value (e.g., a constant voltage corresponding to zero).

Every signed input applied to the set is treated as having a positive magnitude. One of the two wires is always biased as a zero (biased as a constant signal more generally). The other wire carries the magnitude of the input pattern.

In one embodiment, a multi-bit input is represented as a serial or time-sliced input provided on the two wires. For example, the input pattern is a number of bits (e.g., 1101011) for which corresponding voltages are serially applied to the wire, one bit per time slice. In one example, input bits are applied serially one at a time.

In one embodiment, the contribution of output current to common lines from each one of the memory cells varies corresponding to the MSB, MID, or LSB significance of the bit stored by the memory cell (e.g., stored for 3 bits in a group of 3 memory cells above). The contribution for MSB significance (e.g., 100 nA) is two times greater than for MID significance (e.g., 50 nA). The contribution for MID significance is two times greater than for LSB significance (e.g., 25 nA).

When the output current contribution takes bit significance into consideration, then left shifting is not required when adding the signed results (e.g., first, second, third, and fourth signed results) to obtain a signed accumulation result. Instead, the signed results can be added directly without left shifting.

In one embodiment, a memory device performs analog summation of 1-bit result currents having different bit significance implemented via different bias levels. A memory cell (e.g., a RRAM cell or NAND flash memory cell) can be programmed to have exponentially increased (e.g., increasing by powers of two) current for different bias levels.

In one embodiment, a memory cell can be programmed to have a threshold with exponentially increased current for higher bias/applied voltage. A first voltage can be applied to the memory cell to allow a predetermined amount of current (indicated as 1×) to go through to represent a bit value of 1 for the least significant bit.

To represent a bit value of 1 for the second least significant bit, a second voltage can be applied to the memory cell to allow twice (indicated as 2×) the predetermined amount of current to go through, which is equal to the predetermined amount of current multiplied by the bit significance of the second least significant bit.

The memory cell can be similarly biased to have a higher amount of current equal to the predetermined amount of current multiplied by the bit significance of the bit when the bit value is 1.

When different voltages are applied to memory cells each representing one bit in a number such that the respective bit significance of each cell is built into the output currents as described above, the multiplication results involving the memory cells can be summed via connecting them to a line without having to convert the currents for the bits separately for summation.

For example, a 3-bit-resolution weight can be implemented using three memory cells. Each memory cell stores 1-bit of the 3-bit weight. Each memory cell is biased at a separate voltage level such that if it is programmed at a state representing 1, the current going through the cell is a base unit times the bit significance of the cell. For example, the current going through the cell storing the least significant bit (LSB) is a base unit of 25 nA, the cell storing the middle bit (MID) 2 times (2×) the base unit (50 nA), and the most significant bit (MSB) 4 times (4×) the base unit (100 nA).

In one embodiment, a solid-state drive (SSD) or other storage device uses a memory cell array having memory cells. In one example, resistive random-access memory (RRAM) cells are used. In one example, NAND or NOR flash memory cells are used.

In one embodiment, each memory cell is programmable to store one bit of a multi-bit weight. After being programmed, voltage drivers apply different voltages to bias the memory cells for use in performing multiplication. Inputs to be multiplied by the multi-bit weights can be represented by a respective input pattern applied to select gates of select transistors coupled to the memory cells (e.g., as described above), or by varying the different voltages between a fixed voltage state representing an input bit of 1 and a zero state representing an input bit of 0.

One or more common lines are coupled to the memory cells. The lines receive one or more output currents from the memory cells (e.g., as described above). Each common line (e.g., bitline) is used to accumulate the currents to sum the output currents.

In one embodiment, three memory cells store values representing three bits of a stored weight. One bit is for an MSB, one bit is for a bit of middle significance (sometimes indicated as “MID” herein), and one bit is for an LSB. This provides a multi-bit representation for the stored weight.

In one example, when programming memory cells, programming for individual cells is adjusted due to predicted IR drop, etc. For example, a controller shifts each cell threshold voltage during programming so that the initial current during programming is at a higher level. It is noted that during placement (programming), current levels are typically lower because individual cells are targeted for programming. Thus, the drain voltage tends to be much closer to the driver output voltage (and IR drop is minimal or much reduced). In contrast, during inference, many pillars can be selected for example, so bitline currents can be relatively high, which causes a large IR drop.

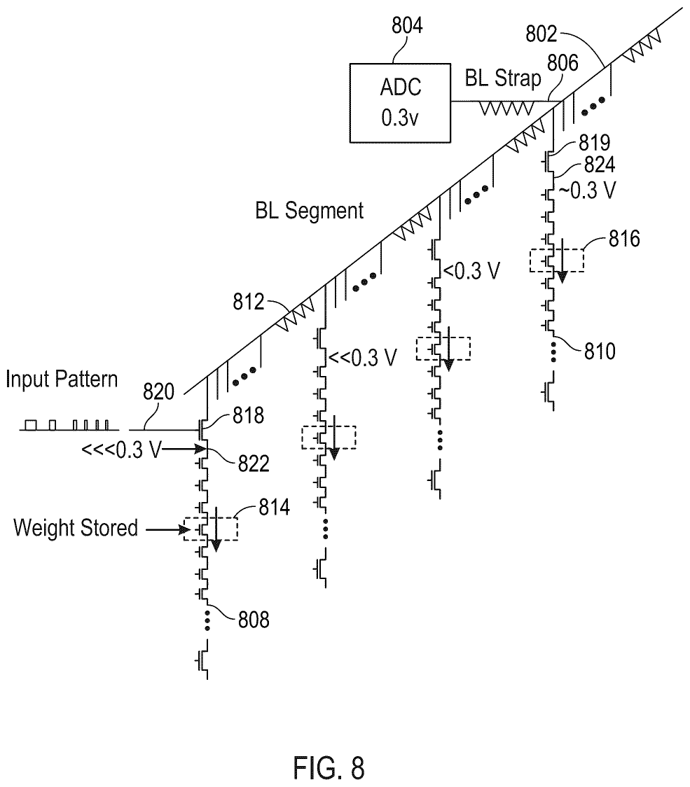

FIG. 8 shows strings of memory cells connected to a common bitline segment 802 according to one embodiment. For example, strings 808, 810 are connected to bitline segment 802. Each string contains memory cells connected in series to select transistors 818, 819. An input pattern 820 for a multiplication operation is applied to gates of select transistors 818, 819.

Voltage driver 804 applies a voltage to bitline segment 802 using bitline strap 806. In one embodiment, bitline strap 806 is connected to other bitline segments (not shown). In one example, voltage driver 804 includes an analog-to-digital (ADC) converter. In one example, voltage driver 804 applies a voltage of 0.3 V to bitline strap 806.

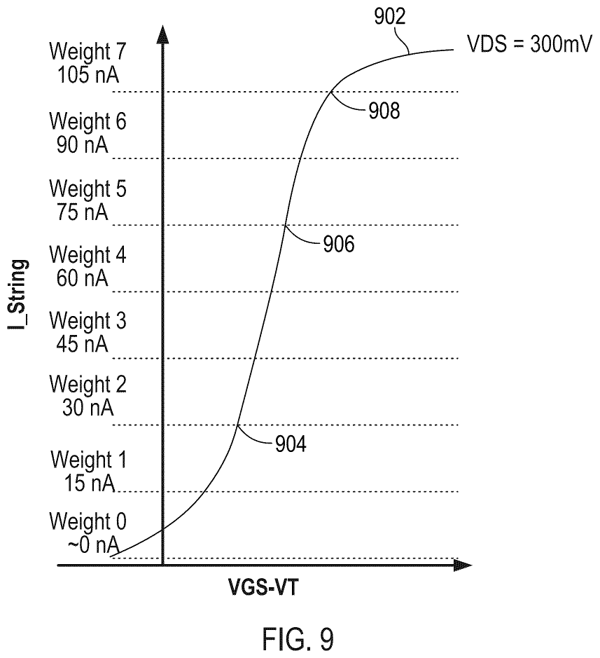

Weights are stored in memory cells of each string. For example, memory cells 814, 816 are programmed to store weights by programming to an adjusted threshold voltage or adjusted target current. During multiplication operations, a cell current (e.g., I_String of FIG. 9) flows through each of memory cells 814, 816, for example.

During multiplication operations, current from one or more of the strings flows through bitline segment 802 (e.g., as output currents are accumulated from multiple strings). This causes voltage drops due to the parasitic resistance 812 of various portions of the bitline segment 802. The voltage drops are of greater magnitude as the distance along bitline segment 802 through which the current flows increases. For example, strings that are closer to voltage driver 804 have a drain voltage 824 that is closer in magnitude to the voltage applied by voltage driver 804. Strings that are further from voltage driver 804 have a drain voltage 822 (e.g., significantly lower than 0.3 V applied by voltage driver 804) that exhibits a more significant voltage drop as compared to strings that are closer to voltage driver 804.

FIG. 9 shows exemplary target currents on an I-V curve 902 of a memory cell with each target current corresponding to a different weight value. The illustrated graph plots a string current I_String versus VGS-VT, which is a gate voltage VGS applied to a selected memory cell minus the threshold voltage VT of the cell. Curve 902 corresponds to a drain voltage VDS applied to the memory cell.

Each of several weight values Weight0 to Weight7 corresponds to a magnitude of output current (see, e.g., points 904, 906, 908 on I-V curve 902) from the memory cell during multiplication. For example, Weight7 corresponds to an output current of 105 nA. It is desired that these output currents be stable during multiplication so that the result from the multiplication is accurate. In one example, these weights provide initial weight targets that can be provided by a host when programming memory cells to support multiplication for a given layer of a neural network.

FIG. 10 shows a bitline used to access multi-pillar memory cells of a memory array according to one embodiment. The bitline includes two bitline segments 1002, 1004 that are electrically connected. For example, bitline segments 1002, 1004 are electrically shorted together using conductive shunts 1050, 1052.

In one embodiment, shunts 1050, 1052 are formed as a part of the same conductive layer used to form the bitline segments 1002, 1004. In one example, the conductive layer is a top metal layer of a NAND flash memory array.

In various embodiments, the shunts can be located at various different positions along the bitline. The sizes of the shunts can vary. In one example, the shunt can be a portion of the conductive layer that extends for more than 50% of the length of the bitline.

By electrically shorting the bitline segments 1002, 1004, the bitline effectively operates as a single logical bitline used to access memory cells of a memory cell array (e.g., 113) storing weights for a neural network. Each memory cell stores a single weight. Each memory cell includes at least one transistor from each of two or more rows of pillars underlying the bitline.

For example, transistor 1030 from pillar 1006 and transistor 1040 from pillar 1008 together provide a single memory cell that stores a single weight. This single memory cell provides a total output current that is accumulated on the bitline. The total output current corresponds to the stored weight. The total output current includes two component currents. A first current is provided by transistor 1030, and a second current is provided by transistor 1040.

Pillars 1006, 1008 are electrically connected to the bitline by select gate transistors 1032, 1042. The same input pattern for a multiplication is provided to the gates of select transistors 1032, 1042. When performing multiplication, the memory cell is selected by applying a bias to the gates of transistors 1030, 1040 using a common wordline (not shown).

In this manner, other memory cells configured using transistors from two or more pillars provide contributions of output current to the bitline. Output currents are accumulated from multiple pillars and a total accumulated current is sensed by sensing circuitry 1020. For example, the total accumulated current corresponds to a digital result from a matrix vector multiplication of the input pattern multiplied by the weights stored in the multi-pillar memory cells.

In one example, each multi-pillar memory cell uses a transistor from at least two adjacent pillars. In one example, each multi-pillar memory cell uses a transistor from at least three or more pillars.

In one embodiment, the bitline is formed overlying rows of the pillars. For example, a first row of pillars includes pillars 1006 and 1010. A second row of pillars includes pillars 1008 and 1012. The multi-pillar memory cells that are electrically connected to the bitline use at least one transistor from each of the two different rows of pillars. In one example, the rows of pillars are adjacent to one another in the memory array.

In one embodiment, the distance between bitline segments 1002, 1004 as used in a layout for manufacturing an integrated circuit is consistently used for some or all bitline segments. For example, a constant pitch in a mask used for a lithography process to form the bitlines is used to layout the bitlines.

In one example, the constant pitch corresponds to a pitch used for laying out bitlines for single pillar memory cells. In one example, the single pillar memory cells correspond to transistors 814, 816 as shown in FIG. 8. In this single pillar memory cell approach, a single bitline segment 802 overlies a single row of pillars.

In some cases, the thickness of the single bitline segment 802 is sufficiently narrow such that the resistance is higher than desired, leading to increased IR drop. In one embodiment, to reduce such IR drop, bitline segments 1002, 1004 are drawn in a layout mask as a single connected metal layer (see, e.g., FIG. 12). This reduces the resistance of the effective bitline in the electrical circuit path to the multi-pillar memory cells, and thus decreases IR drop.

In one embodiment, a memory device can be formed using both single pillar memory cells and multi-pillar memory cells. For example, the layout mask can define a portion of the metal layer to provide bitline segments that connect to single pillar memory cells. A different portion of the layout mask can define bitline segments that are electrically shorted for use with multi-pillar memory cells.

In one embodiment, shunt 1050, 1052 can be formed from a conductive layer that is different than the conductive layer used to form the bitline segments. For example, the conductive layer (not shown) forming the shunt can be above or below the height of the conductive layer forming the bitline segments. Vias or other interconnect (not shown) can be used to electrically connect these two conductive layers (shunt and bitline) as needed to perform the electrical shorting of the bitline segments.

In one embodiment, the two transistors forming a multi-pillar memory cell have the same input signals applied, and/or they have the same tier level selection control (e.g., using a common wordline). This is somewhat like increasing the size of each memory cell. The two transistors act as a single memory cell storing a weight.

As an example, if a target output current for a given weight is 200 nanoamps (nA), then the use of two transistors reduces the current through each cell down to about 100 nano amps. This reduces the loading on each pillar. So, for example, the target output current can be safely increased to, for example, 300 nanoamps when using two pillars in parallel.

In one embodiment, a memory device or memory arrays can use the double bitline configuration with multi-pillar memory cells in a first portion of the device or array, and a single bitline configuration with single pillar memory cells in a second portion of the device or array depending on anticipated current demands for multiplication. For example, a controller can select the first or second portion to use depending on expected current demands (e.g., for a given layer of a neural network) based on knowing information about weights, the AI model, etc.

In one embodiment, controller operation when using the two bitline segments shorted together is basically the same as for single bitline usage. The two transistors in each memory cell are programmed and read together as a single unit.

In one embodiment, the multi-pillar memory cell approach can be applied to storing weights for more significant bits, which often have higher currents. The single bitline approach with single pillar memory cells can be used for least significant bits, which often have lower currents. These two approaches can be used in different portions of a memory array or device.

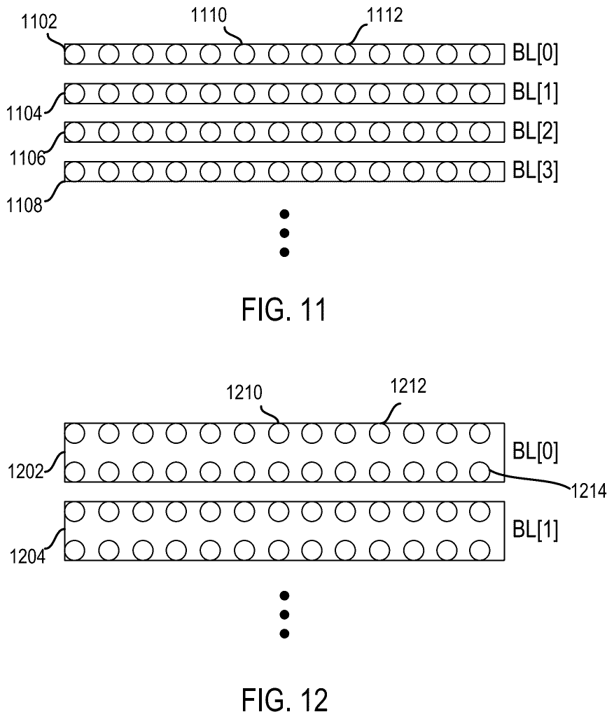

FIG. 11 shows a top view of bitlines used to access single pillar memory cells. Each bitline segment 1102, 1104, 1106, 1108 operates as a single logical bitline used to access memory cells in a row of pillars underlying the memory cell. For example, bitline segment 1102 accesses memory cells in pillars 1110, 1112. In one example, the top view of the bitline segments is from a top perspective such as looking down on bitline segment 802 of FIG. 8.

In one example, each bitline segment has a layout pitch that is constant, such as described above. In some cases, the width of the bitline segments is narrower than desired, which can lead to undesirably increased IR drops.

FIG. 12 shows a top view of bitlines used to access multi-pillar memory cells according to one embodiment. In one example, this top view is a view looking down on the bitline of FIG. 10.

In one embodiment, bitline segments 1102, 1104 are drawn in a layout mask so that a single effective bitline 1202 is provided. Similarly, bitline segments 1106, 1108 are drawn to provide a single effective bitline 1204. In one example, the effective bitline 1202 corresponds to electrically shorting bitline segments 1002, 1004 of FIG. 10.

Bitline 1202 overlies pillars 1210, 1212, 1214. In one example, these pillars are arranged in adjacent rows of the memory array. Increasing the width of each effective bitline 1202, 1204 reduces resistance so that IR drop is reduced.

Bitlines 1202, 1204 are illustrated as being formed by combining pairs of adjacent bitline segments (e.g., 1102, 1104). However, in other embodiments, three more adjacent bitline segments can be combined to provide a single effective bitline. For example, all bitline segments 1102, 1104, 1106, 1108 can be combined to provide a single logical bitline. In this case, each multi-pillar memory cell can use a transistor from each of the different rows of pillars underlying the different bitline segments. In one example, each bitline 1202, 1204 is connected to sensing circuitry (e.g., 1020).

In one example, there is a vertical connection from each bitline to a driver located in an underlying semiconductor substrate. Supporting circuitry can be located under the memory array on the semiconductor substrate.

In some cases, shunting of bitlines together as described herein may permit adding more tiers in the vertical direction. This is because the current through any given pillar can be lower than in the single bitline approach. The shunting approach may also permit using an existing NAND manufacturing approach, but adding additional tiers, because the shunting reduces the load on any given pillar/cell.

FIG. 13 shows an architecture having resistive random access memory (RRAM) or NOR memory cells arranged in a parallel configuration for performing multiplication (e.g., MVM) according to one embodiment. For example, memory cells 1330, 1331, 1332 of memory cell array 1302 store bits of respective significance for a multi-bit weight (indicated as Weight1). A simple 3-bit weight is illustrated, but a larger number of bits can be stored for each weight. When performing multiplication, each of memory cells 1330, 1331, 1332 can be accessed in parallel. In one example, memory cell array 1302 includes memory cells arranged as illustrated in FIG. 6.

Each memory cell provides an output current that corresponds to a significance of a bit stored by the memory cell. Memory cells 1330, 1331, 1332 are connected to a common line 1310 for accumulating output currents. In one example, line 1310 is a bitline.

Different voltages V1, V2, V3 are applied to memory cells 1330, 1331, 1332 using wordlines 1320, 1321, 1322. Voltages are selected so that the output currents vary by a power of two based on bit significance, for example as described above.

In one embodiment, an input signal 11 is applied to the gate of select transistor 1340. Select transistor 1340 is coupled to common line 1310. An output of select transistor 1340 provides a sum of the output currents. In one embodiment, when the input signal is applied to the gate of select transistor 1340, the different voltages V1, V2, V3 are held at a constant voltage level.

In an alternative embodiment, an input pattern for multiplication by Weight1 can be applied to wordlines 1320, 1321, 1322 by varying the different voltages V1, V2, V3 between fixed voltages and zero voltages similarly as described above to represent input bits of 1 or 0, respectively.

Memory cell array 1302 is formed above semiconductor substrate 1304. In one embodiment, memory cell array 1302 and semiconductor substrate 1304 are located on different chips or wafers prior to being assembled (e.g., being joined by bonding).

Similarly, as described above for Weight1, multi-bit weights Weight2 and Weight3 can be stored in other memory cells of memory cell array 1302, and output currents accumulated on common lines 1311, 1312, as illustrated. These other memory cells can be accessed using wordlines 1320, 1321, 1322. Common lines 1311, 1312 are coupled to select transistors 1341, 1342, which each provide a sum of output currents as an output. Input patterns 12, 13 can be applied to gates of the select transistors. Additional weights can be stored in memory cell array 1302.

Output currents from common lines 1310, 1311, 1312 are accumulated by accumulation circuitry 1350. In one embodiment, accumulation circuitry 1350 is formed in semiconductor substrate 1304 (e.g., formed at a top surface).

In one embodiment, voltage drivers 1306 and biasing circuitry 1305 are formed in semiconductor substrate 1304. Logic circuitry (not shown) formed in semiconductor substrate 1304 is used to implement controller 1303. Controller 1303 controls voltage drivers 1306 and biasing circuitry 1305.

In one embodiment, voltage drivers 1306 provide the different voltages V1, V2, V3. Each voltage is adjusted based on a context of the memory cell array determined by a controller (e.g., 124, 161). Biasing circuitry 1305 applies inputs 11, 12, 13.

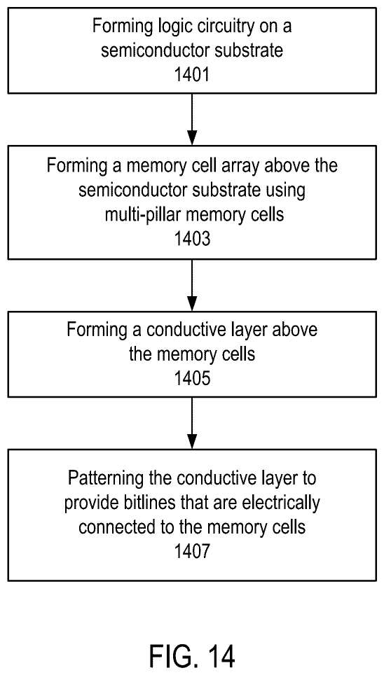

FIG. 14 shows a method for forming a memory device having multi-pillar memory cells for use when performing multiplication according to one embodiment. For example, the method of FIG. 14 can be performed in integrated circuit device 101 of FIG. 1 (e.g., as described in various embodiments above).

The method of FIG. 14 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 14 is performed at least in part by one or more processing devices (e.g., controller 124 and/or 161 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1401, logic circuitry is formed on a semiconductor substrate. In one example, the logic circuitry is inference logic circuit 123.

At block 1403, a memory cell array is formed above the semiconductor substrate. The memory cell array uses multi-pillar memory cells. In one example, the memory cell array is array 113.

At block 1405, a conductive layer is formed above the memory cells. In one example, the conductive layer is a metal layer used to form bitlines in a NAND flash memory array.

At block 1407, the conductive layer is patterned to provide bitlines (see, e.g., FIG. 12). The bitlines are electrically connected to the memory cells for accumulating output currents from the memory cells. In one example, the bitlines accumulate output currents from transistors connected in series. In one example, the transistors are configured in pillars 1006, 1008, 1010, 1012.

In one example, weights stored in multi-pillar memory cells of FIG. 10 are multiplied by one or more input patterns by summing output currents from the memory cells using bitline segments 1002, 1004. In one example, accumulation circuitry accumulates output currents on the bitline and generates a digital result corresponding to the sum of the output currents.

In one embodiment, a memory device comprises: a semiconductor substrate; a memory array (e.g., 113) having memory cells, the memory array extending vertically above the semiconductor substrate, and the memory array comprising at least one first pillar (e.g., 1006, 1010) of transistors (e.g., a first row of pillars) and at least one second pillar (e.g., 1008, 1012) of transistors (e.g., a second row of pillars running parallel to the first row), wherein each memory cell includes a respective first transistor from the first pillar and a respective second transistor from the second pillar; and a bitline (e.g., bitline segments 1002, 1004 are electrically shorted to provide an effective single bitline) overlying the first and second pillars, wherein the bitline is electrically connected to the first and second pillars, and the bitline is configured to accumulate output currents from the first and second pillars when performing multiplication (e.g., MVM).

In one embodiment, each transistor is a NAND flash transistor.

In one embodiment, the device further comprises a wordline configured to select a first memory cell, wherein the wordline is connected to gates of the respective first and second transistors of the first memory cell, and wherein the bitline is configured to accumulate an output current from the first memory cell (e.g., the output current is provided by substantially equal current from each of the first and second transistors).

In one embodiment, each of the first and second pillars is electrically connected to the bitline (e.g., first and second parallel rows of pillars are connected to the same common bitline) by select transistors (e.g., 1032, 1042). At least one input pattern for the multiplication is applied to gates of the select transistors.

In one embodiment, the device further comprises an accumulator to accumulate the output currents from the multiplication and provide a digital result of the multiplication.

In one embodiment, each memory cell (e.g., memory cell using transistors 1030, 1040) is configured to store a weight used in the multiplication when the memory cell has been selected.

In one embodiment, each memory cell is programmed to store the weight, and the first and second transistors of the memory cell are programmed in parallel.

In one embodiment, the first and second transistors of each memory cell are programmed to store a respective weight so that a sum of output currents from the first and second transistors during the multiplication corresponds to a target current for the respective weight (e.g., each of the first and second transistors is configured to provide half of the target current).

In one embodiment, a method comprises: forming logic circuitry on a semiconductor substrate; forming a memory cell array above the semiconductor substrate, the memory cell array including pillars, wherein each pillar has transistors connected in series, each pillar extends vertically above the semiconductor substrate, and each of a plurality of first memory cells includes a respective first transistor of first pillars and a respective second transistor of second pillars; forming a conductive layer above the pillars; and patterning the conductive layer to provide bitlines (e.g., 1202, 1204) that are electrically connected to the pillars (e.g., 1210, 1214), wherein the bitlines include a first bitline used to access the first memory cells.

The logic circuitry is configured to: program the first memory cells to store first weights for a neural network; and after programming the first memory cells, perform a multiplication based on accumulating output currents from the first memory cells using the first bitline.

In one embodiment, the first memory cells are coupled to the first bitline by select transistors, and performing the multiplication comprises applying at least one input pattern to gates of the select transistors.

In one embodiment, the method further comprises: applying, during the multiplication and using at least one voltage driver, a bias to the first bitline; and determining an accumulation result from the multiplication by measuring a sum of the output currents using sensing circuitry coupled to the first bitline.

In one embodiment, the first bitline includes first and second bitline segments (e.g., 1002, 1004) that are electrically connected to configure the first bitline for operation as a single logical bitline.

In one embodiment, the method further comprises forming at least one shunt (e.g., 1050, 1052), wherein the first and second bitline segments are electrically connected by the shunt.

In one embodiment, the conductive layer is a first conductive layer, and the shunt is formed using a second conductive layer (e.g., a metal layer) located at a vertical height relative to the semiconductor substrate that is above or below a vertical height of the first conductive layer.

In one embodiment, the first pillars are configured in a first row; the second pillars are configured in a second row; and the first bitline is formed overlying the first and second rows.

In one embodiment, the method further comprises forming voltage drivers on the semiconductor substrate, and forming vertical interconnects (e.g., vias) to connect the voltage drivers to the bitlines.

In one embodiment, an apparatus comprises: a host interface configured to communicate with a host; a memory cell array comprising memory cells configured to store weights, and access lines configured to access the memory cells.

The array includes rows of pillars. Each pillar has transistors electrically connected in series, and each memory cell of the array includes respective transistors from at least two respective pillars located in adjacent rows of the pillars (e.g., a memory cell includes a transistor from each of four adjacent pillars).

The array also includes logic circuitry configured to: receive, via the host interface from the host, first weights for a neural network; program first memory cells to store the first weights; and perform multiplication of the first weights by first inputs by summing output currents from the first memory cells.

In one embodiment, the memory cells are resistive random access memory (RRAM) cells, phase-change memory (PCM) cells, NOR flash memory cells, or NAND flash memory cells.

In one embodiment, the access lines are bitlines overlying the pillars.

In one embodiment, the apparatus further comprises sensing circuitry coupled to the bitlines and configured to measure output currents from the memory cells.

Various embodiments related to memory devices that apply a fixed gate bias to memory cells are now described below. The generality of the following description is not limited by the various embodiments described above. In various embodiments, the fixed gate bias is applied to the memory cells when the cells are programmed and/or used for multiplication. Output currents from the memory cells are measured to perform the programming. A target output current used for controlling the programming corresponds to a weight to be stored. Output currents from the programmed memory cells are accumulated to perform the multiplication.

Prior NAND technology devices typically use memory cells that are biased at low current magnitude ranges (e.g., 10-20 nA). The memory cell states are placed to achieve a multi-level capability using programming algorithms that rely on threshold voltage (Vt) measurements at a constant target current.

In one example, the threshold voltage of a memory cell is set by changing the amount of charge on a floating gate of a transistor of the cell (e.g., floating gate memory cells), or changing the amount of trapped charge on an interface of the cell (e.g., charges embedded within a material of the cell, as for charge trap memory cells). A common approach for NAND memory is to find a threshold voltage of a cell by varying an applied gate voltage. The threshold voltage corresponds to the voltage at which the cell current reaches a defined low-level value (e.g., constant sense current).

A NAND memory array structure is often built in pillars or strings of transistors that are used as memory cells. The vertical pillars are intersected by horizontal wordlines (e.g., formed as conductive wordline layers). Along each horizontal tier, at the intersection of a slice and a pillar is one memory cell. The state of a memory cell is set by placing the threshold of the memory cell in a specific way. For example, the threshold voltage of an individual cell is measured during placement (e.g., programming or erasing to set the threshold of the cell) to meet a target value.

In one example for setting a NAND memory cell threshold, a programming pulse is applied to the cell using a high-voltage on the gate and biasing the cell in some defined condition. Then, a measurement is performed to determine the threshold of the cell. In one example, the VDS or pillar voltage applied to a pillar corresponds to a very low sense current through the cell (e.g., 20 nA).

The threshold is measured by varying the gate voltage applied to the cell to determine the voltage that causes the sense current to flow. This is sometimes referred to as threshold voltage-based placement. The placement of a cell generally involves programming the cell, measuring the cell, then programming the cell again as needed for fine-tuning to reach a desired cell state.

However, the above manner of biasing NAND memory devices creates a technical problem because it is not compatible with the requirements for efficiently performing MVM calculations in a memory device. Biasing NAND cells so that currents are small such as described above causes significant variability, which is undesirable for MVM calculations.

For example, the threshold voltage sensitivity of string current in a NAND memory device is significantly large at the small, constant sense current (e.g., ˜20 nA) used for placement and sensing. This large variation inhibits MVM operation with the accuracy desired for effective artificial intelligence (AI) applications.

For example, the cell current variation relative to a static or average current is significantly large for standard NAND memory cell operation.

To address the above technical problems of standard NAND devices, a memory device uses memory cells for multiplication in which a fixed gate bias is applied to the memory cells. In one embodiment, a memory device that supports AI applications (e.g., matrix vector multiplication (MVM)) uses a structure similar to NAND cells, but the cells are biased in a different region of operation by targeting larger string currents (e.g., 100-200 nA) than are used for standard NAND devices. Also, the cell states are placed by using current measurements at a constant applied voltage as opposed to threshold measurements at a constant current. By operating NAND cells in this way, an array of synaptic connections of various weight levels can be defined with sufficiently reduced cell variability (relative to standard NAND biasing) to achieve the desired sum of products computations within acceptable target error tolerances.

The higher currents and use of parallel cell operation above can contribute a relatively larger IR drop during MVM operation as compared to standard NAND devices (e.g., IR drop along the current-carrying bitline (BL) electrodes). In various embodiments, this IR drop can be mitigated by use of one or more of the following:
Splitting the memory arrays into more compact sub-arrays.
Building a shunting network with additional metal layers to reduce bitline resistance.
Modification of the bitline electrode process to use less resistive materials or larger cross-sectional aspect ratios.
Adjustment of pillar voltage during operation.
Adjustment of the pass voltage (VPASS) level during read/verify/MVM.
Selection of the Id-Vg-Vth point of operation of the cell in a string.
Current-based sensing or state detection method.
Placement method used to compensate for the larger IR drops based on location in an array.
Adjustment of cell threshold and/or current distribution targets to support sum of products calculations.

MVM involves a parallel computation of the dot-product or sum of products of an input vector against a large number of stored vectors, the output of which is another vector. A NAND array and memory cells operated as described herein can be used for this MVM computation.

In one embodiment, a memory device includes memory cells (e.g., NAND flash memory cells) configured in one or more memory dies, and a controller. The controller performs initial programming of each memory cell. After the initial programming, an output current from each memory cell is measured by applying a fixed bias to a gate of the memory cell. Based on the respective output current that is measured for each cell, additional programming of each cell is performed. An output current from each cell is again measured with the fixed bias applied to the gate of the cell. The additional programming is continued (e.g., in one or more steps) until the measured output current obtained from the respective memory cell corresponds to a desired stored weight. In one example, the initial and/or additional programming includes applying one or more voltage pulses to the memory cell.

In one embodiment, the controller, after programming the memory cells, performs multiplication by summing output currents from the memory cells based on inputs that are applied to the memory cells. During the multiplication, the fixed bias is applied to the gate of each memory cell to provide the output currents. In one example, a wordline is coupled to the gate of each memory cell, and the fixed bias is applied using the wordline.

In one embodiment, an approach is used in which the voltage applied to the gate of the memory cells is not moved after programming the cells. The threshold voltage is not measured, and instead a controller measures the amount of current that each cell generates at a specific bias condition. This is done by applying a constant voltage on the gate of the cell and then measuring the output current. If the output current is too high or too low compared to a target current that corresponds to a stored weight, the controller goes back into a programming pulsing sequence to adjust the threshold of the cell. The controller programs each cell, measures the cell, then programs again as needed to fine-tune the cell to reach the desired state.

As mentioned above, standard NAND cells have significant variability, which is undesirable for MVM. Various embodiments described herein change the bias of the cells to a higher current regime of operation as compared to standard NAND memory operation. This significantly reduces variability of the cell. Also, due to the higher current magnitudes used, the noise relative to the average current (e.g., as expressed by a signal to noise ratio) is improved.

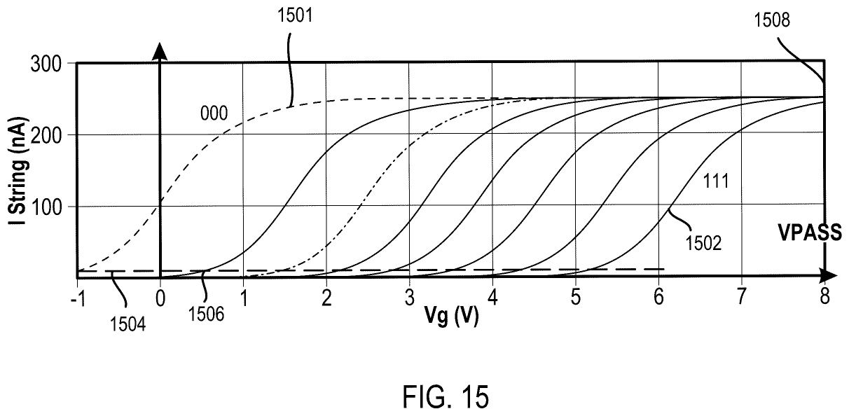

FIG. 15 shows an exemplary graph of string current vs. gate voltage for a memory cell in a string of cells in a standard NAND memory device. The memory cell stores a 3-bit value (3 bits per cell).

The illustrated curves (e.g., 1501, 1502) represent different states of the cell. Curve 1501 is for an erased state having a value of 000. Curve 1502 is for a programmed state having a value of 111.

In one example, a voltage Vstring is applied across the string. Gate voltage (Vg) is applied to the gate of the target cell in the string. There is a selector device at the top of the string and a selector device at the bottom of the string. A pass voltage 1508 (VPASS) is applied to all other cells in the string.

Line 1506 represents a constant sense current level used to determine a threshold voltage of the cell. A controller varies the gate voltage until a string current is sensed that corresponds to the magnitude of the constant sense current (e.g., 20 nA). That gate voltage is determined as the threshold voltage for the cell. Threshold voltages as illustrated range from about −1 V to 5 V. VPASS is 8 V.

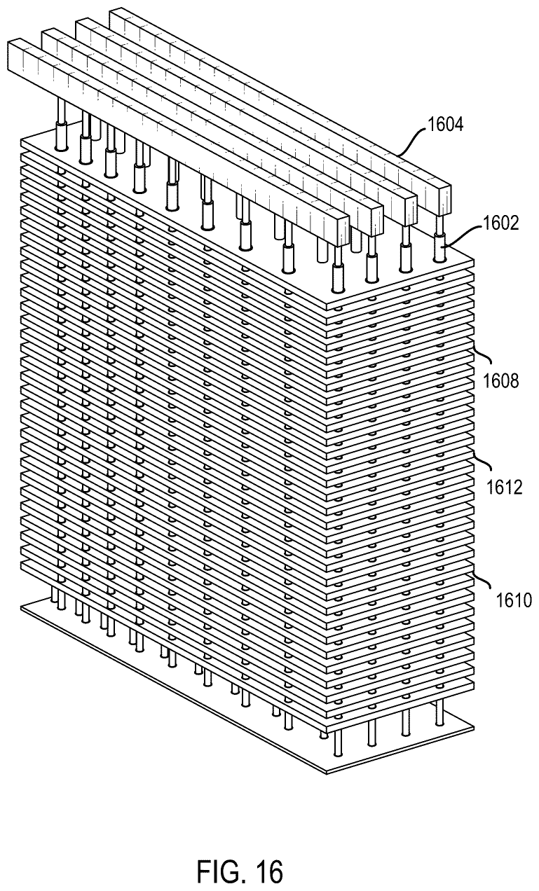

FIG. 16 shows a memory array having vertical pillars 1602 of memory cells according to one embodiment. Each pillar 1602 includes memory cells connected in series as a string. Each memory cell is, for example, a physical transistor having a gate that controls current flow through the transistor. Other memory cells can include transistors from more than one pillar.

Horizontal tiers 1608, 1610, 1612 intersect pillars 1602. A memory cell is located at the intersection of each tier and a pillar. For example, each tier is a wordline used to provide a gate voltage on the gate for each memory cell. In one example, the tiers are formed as conductive layers located above a semiconductor substrate (not shown).

During programming of memory cells, a fixed gate bias is applied using the wordlines. For example, a controller adjusts the threshold voltage of each memory cell to reach an appropriate level of current. Measured as a threshold of the cell, each different level of current corresponds to a different state (e.g., 000, 010, 110, 111, etc.) of the cell.

When performing multiplication, output currents from active memory cells are accumulated using bitlines 1604. Output currents from multiple pillars 1602 are accumulated on a single bitline 1604.

The active memory cells are biased to a fixed gate bias using, for example, active tier 1612. A pass voltage is applied to the other tiers 1608, 1610 that are not active for the particular multiplication being performed. During the multiplication, the fixed gate bias is applied to the active memory cells. Output currents from the active cells are accumulated on bitline 1604. The accumulated current is converted into a digital representation (e.g., an analog to digital conversion) (e.g., using accumulation circuitry as described above).

In one example, for any given pillar, a controller selects only one active tier. The controller biases all wordlines so all memory cells in the string of memory cells arranged vertically in the pillar are conductive. The active memory cell receives the fixed gate bias used during placement by the programming. The other cells receive a pass voltage and are conducting and turned fully on. The overall resistance of the pillar is modulated by the selected active tier.

In one example, multiple pillars are connected to a bitline and are conducting at the same time. One of the tiers has been activated and multiple cells of the different multiple pillars are conducting at the same time. This tends to result in higher currents flowing through the bitlines and pillars, which increases IR drop. The current is higher because multiple cells are being selected for a given bitline. For example, the average current is higher as compared to standard NAND memory devices.

In one example, bitlines 1604 are relatively long and narrow and exhibit higher resistance as a result. In one example, tungsten is used to form the bitlines, which contributes to this resistance. A typical array size may have, for example, a thousand pillars arranged in the bitline direction. To reduce IR drop, the array can be formed as multiple sub-arrays instead of a single array. For example, the array can be broken into four bitline segments and then those segments can be shunted together.

In one embodiment, the material used to form the bitlines is selected to have a lower resistivity. In one example, copper is used to form the bitlines. Copper has lower resistivity than tungsten.

In one embodiment, the voltage across the pillar is reduced. This can help lower the IR drop during multiplication.

In one embodiment, programming of the memory cells is adjusted to compensate for IR drop at different locations of the array. For example, programming for each memory cell is adjusted based on a physical location of the cell and the memory array.

Because there are multiple pillars along any given bitline, the data stored in the memory cells of those pillars will also have an effect on the IR drop. This is because each of the conducting pillars increases the total current through the bitline.

In one embodiment, voltage biases applied on any given memory cell are compensated for the expected IR drop. For example, a controller can use a lookup table to select a bias compensation to use. During the actual programming of the different states of the cells in an array, IR drop data is taken into account. For example, this data is used to compensate the actual target voltage or pulses to be applied to a given cell.

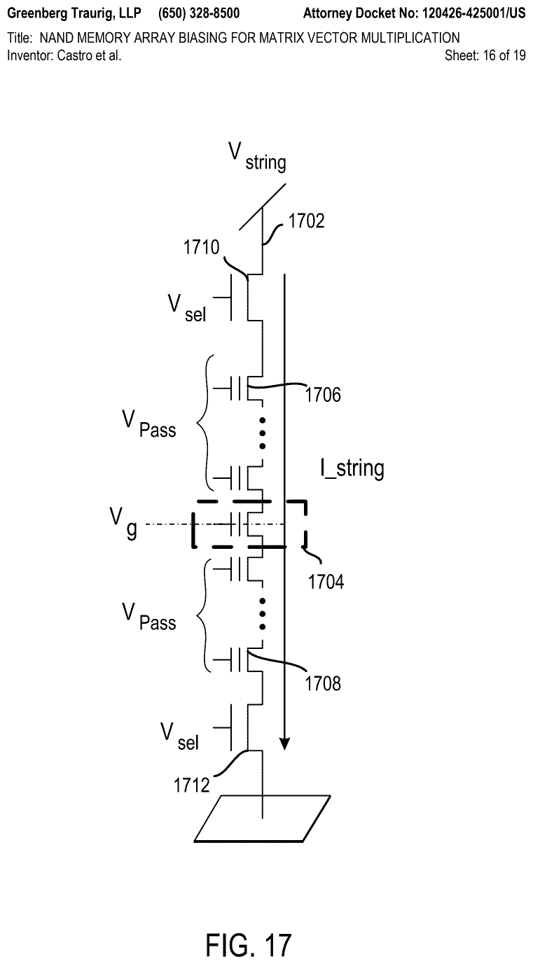

FIG. 17 shows a string 1702 of memory cells having an active cell 1704 to which a gate voltage Vg is applied, and having other non-active cells (e.g., 1706, 1708) to which a pass voltage Vpass is applied according to one embodiment. Vstring is a voltage applied across the string. Vg is a fixed bias applied to the target cell during programming and multiplication.

String 1702 is an example of each pillar 1602 of FIG. 16. Vg is applied using active tier 1612. The pass voltage Vpass is applied using tiers 1608, 1610.

There is a selector 1710 at the top of the string and a selector 1712 at the bottom of the string. Typically, the selector 1712 at the bottom (SGS) is simply biased on. The selector 1710 at the top (SGD) is used for providing inputs to the active cells during multiplication.

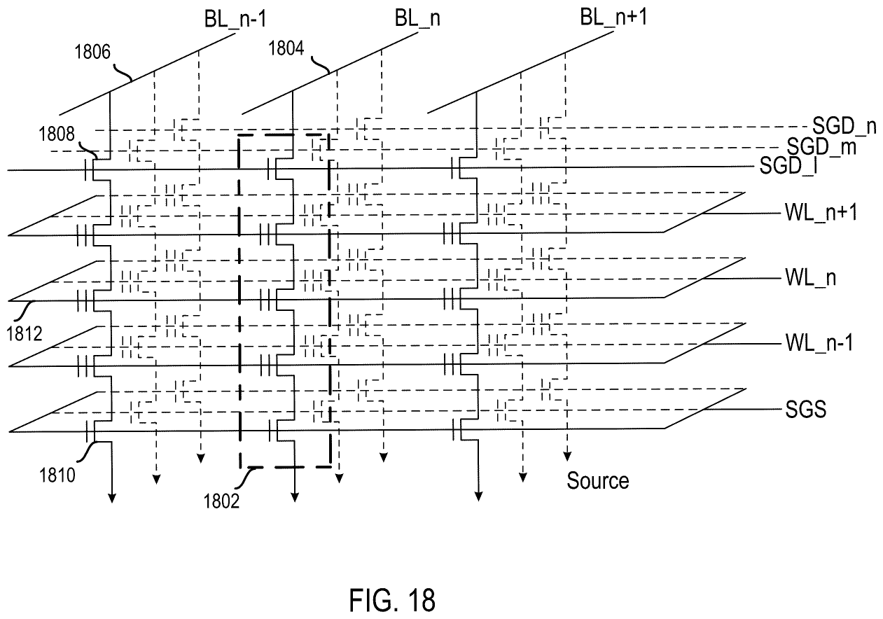

FIG. 18 shows strings 1802 of memory cells connected to bitlines 1804, 1806 used to accumulate output currents from the cells according to one embodiment. String 1802 is an example of pillar 1602 of FIG. 16.

In one example, a NAND array is composed of an array of strings or pillars. Each pillar is composed of a number of tiers. A NAND cell is located at each tier within a pillar. Cells within a tier may share a common wordline (WL) 1812 connection which runs in the plane of each tier.

Each pillar has top and bottom connections. The bottom connections represent the source or plate connection, which is common to a large number of pillars and may be electrically common to all pillars in some cases. The top of each pillar is connected to an array of bitlines (BLs) which are organized to run in an orthogonal direction to the wordlines (WLs).

In addition, each pillar has additional select transistors 1808, 1810 near the bitline BL or near the source (labeled SGS and SGD transistors in FIG. 18). The SGD transistors 1808 are used to decode pillars when multiple pillars on a bitline BL share the same wordline WL (often referred to as a “WL block”).

In one example, the SGS and SGD select transistors 1808, 1810 can be viewed as pillar selectors. The SGD transistors 1808 are used for inputs. Each bitline can be selected individually so that a controller can program an individual cell. The SGD transistors permit selecting an individual cell (since the wordlines are shorted together).

In one example, the source is a ground connection. In some cases, source can be switched to different voltage value depending on the operation mode. In some cases, the source is a common node for a memory chip.

In one example, for a multiplication an input vector Xᵢ having 1,024 values is applied to a series of bitlines (also sometimes referred to as digit lines). At the intersection of each input with a bitline, there is a multiplication that occurs. The input vector Xi is applied at the SGD transistors or selectors 1808. A controller selects one tier 1812 of wordlines in the array and applies the inputs using the selectors 1808.

In one example, each node corresponds to two digit lines and two input lines providing input. This is done in order to represent four quadrants of multiplication. This node configuration permits using positive and negative inputs, positive and negative weights, and obtaining positive and negative outputs.

In one example, there is an integrating circuit (e.g., analog-to-digital conversion circuit) located at and electrically connected to the bottom of each digit line.

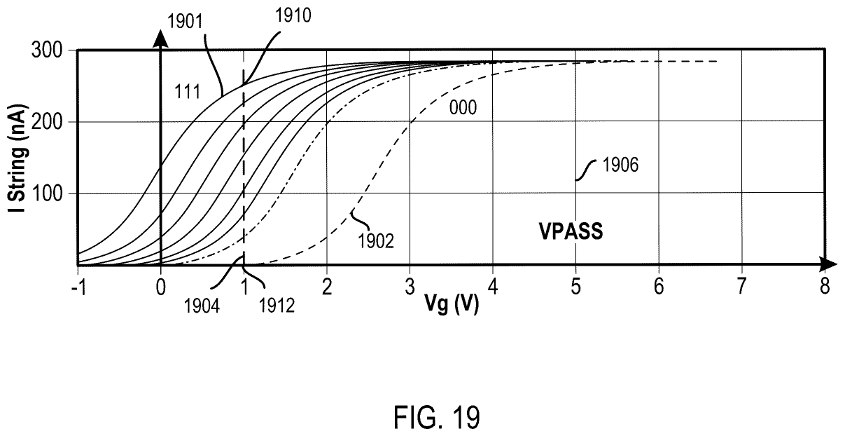

FIG. 19 shows an exemplary graph of string current vs. gate voltage for a memory cell in a string of memory cells in a NAND memory array for which a fixed gate bias is applied to memory cells being used for a multiplication according to one embodiment. The memory cell stores a 3-bit value (3 bits per cell). In one example, the memory cell is memory cell 1704 of FIG. 17.

The illustrated curves (e.g., 1901, 1902) represent different states of the cell. Curve 1902 is for an erased state having a value of 000. Curve 1901 is for a programmed state having a value of 111.

In one example, a voltage Vstring is applied across the string of memory cells. Gate voltage (Vg) is applied to the gate of the target cell in the string. There is a selector device at the top of the string and a selector device at the bottom of the string. A pass voltage 1906 (VPASS) is applied to all other cells in the string.

Dashed vertical line 1904 represents a constant fixed gate bias Vg that is applied to the cell during programming and when performing multiplication. For example, the fixed gate bias is illustrated as 1 V. When this gate bias is applied, the string current varies depending on the state to which the cells programmed. For example, when the cell is programmed to 111, the string current corresponds to point 1910 (about 250 nA). When the cell is erased to 000, the string current corresponds to point 1912 and is zero or negligible.

The differing string currents correspond to output currents from the memory cell that vary depending on the state to which the cell is programmed. For example, for a constant Vg=1V bias, cell thresholds can be set to provide output currents from 0 nA to 245 nA in 35 nA steps.

A controller measures the output current during programming in which the fixed gate bias is applied. The controller uses a series of programming steps. An initial programming is performed, the output current measured, and an additional programming step(s) is done until the output current reaches a target output current corresponding to a desired state. This desired state can correspond to a value of a weight stored by the memory cell.

Threshold voltages as illustrated range from about −1 V to 1 V. VPASS is 5 V. This threshold voltage range is smaller than the threshold voltage range of the standard NAND device as illustrated in FIG. 15. Also, the pass voltage as illustrated is smaller than the pass voltage used for the standard NAND device as illustrated in FIG. 15.

In comparing the operation of the memory cell at a constant gate voltage in FIG. 19 versus the constant sense current operation used for standard NAND as illustrated in FIG. 15, several observations can be made. The threshold voltage (Vt) sensitivity of string current is much larger at the constant sense current for standard NAND (e.g., ˜20 nA) than at the larger currents used for MVM multiplication (e.g., ˜150 nA). The larger current variation (relative to the static or average current) of standard NAND generally prevents MVM operation with sufficient accuracy for AI applications. However, when operating at a fixed gate bias as illustrated in FIG. 19, the expected current variation from 0 to 245 nA is sufficient to support MVM operations.

The SNR (signal to noise ratio, separation between states) needed for MVM operation is significantly smaller than that required for standard NAND memory applications. The separation between states (in Vth space) can be smaller for MVM operation (and its equivalent in current space). Also, because multiples of cells are being used in MVM operations, random cell variations between cells tend to cancel out.

The distribution of weights for neural network applications tends to be centered around a value of 0 (e.g., 000 of curve 1902). The back-pattern effect observed in standard NAND memory devices is smaller for MVM applications. This is, for example, due to the use of a lower pass voltage and/or a smaller difference between the pass voltage and the threshold voltage of the erased state as shown for curve 1902.

For MVM operation, the threshold voltage differences between cells are smaller than for standard NAND cells. Thus, Vpass can be smaller.

In one example regarding the back-pattern effect, on average the pass cells will have a value near zero. The states/curves are closer together (less separation compared to standard NAND devices), so the impact of pass voltage Vpass on the cells will be more similar and uniform than for standard NAND devices.

MVM operation will often involve larger currents and significant IR drop due to highly-resistive bitline metal. In one embodiment, this effect can be mitigated by folding the memory array into sub-arrays and providing a lower resistance shunting network above the memory array. Also, the number of cells in a string can be reduced (e.g., number of tiers reduced to 64 or less).

In addition, a threshold placement method can be provided to compensate for the IR drop expected or determined at the specific array location of a given memory cell. Further, the string voltage (Vstring value) can be targeted to a lower voltage (e.g., ˜300 mV). The zero state in a synapse can be defined as the low current state (e.g., point 1912 of curve 1902).

For MVM operation, the reduced threshold voltage range reduces the separation between cell states (window budget). In one embodiment, this can be mitigated by reducing the pass voltage VPASS value to reduce read disturb. A controller can implement cell refresh cycles more often than used for standard NAND memory components. For example, refresh cycles can be implemented once per week. Also, constant temperature operation can be targeted to reduce or avoid temperature related variations.

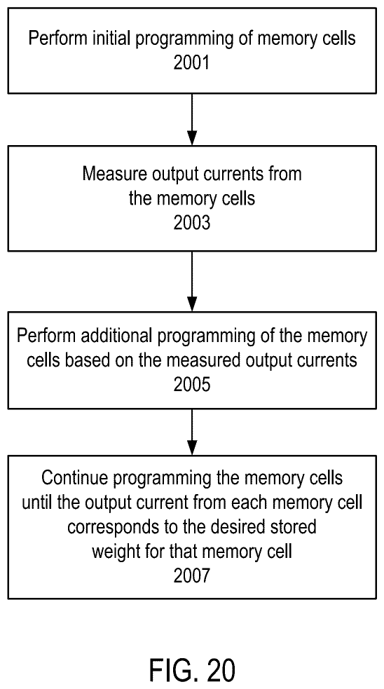

FIG. 20 shows a method for programming memory cells by measuring output currents according to one embodiment. For example, the method of FIG. 20 can be implemented in the system of FIG. 1. In one example, controller 124 of FIG. 1 programs memory cells in memory cell array 113. In one example, the memory cells are programmed to store weights for a neural network. In one example, inputs from sensors 111 are multiplied by weights stored in the programmed memory cells.

The method of FIG. 20 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 20 is performed at least in part by one or more processing devices (e.g., controller 124 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2001, initial programming of memory cells is performed. In one example, memory cells in pillars 1602 are programmed.

At block 2003, output currents from the memory cells are measured. In one example, an output current from a programmed memory cell is measured using sensing circuitry 150. In one example, the measured output current corresponds to point 1910 of curve 1901 in which a fixed gate bias 1904 is applied.

At block 2005, additional programming of the memory cells is performed. The additional programming is configured based on evaluation of the measured output currents from the initial programming. The additional programming can be performed in one or more pulses based on the evaluation. The additional programming can vary the magnitude of the programming voltage and/or the polarity of the voltage based on the measured output currents. The initial and/or the additional programming can be varied based on the physical location of the memory cell in the memory array.

At block 2007, programming of the memory cells is continued. As continued programming is performed, new measurements of output currents from the memory cells are made. The continued programming is adjusted based on the new measurements made. Alternating of programming and measuring of output currents is continued until the output current is equal to a target output current within a defined tolerance (e.g., 1 to 5%). For example, the target output current corresponds to a weight to be stored in the memory cell.

In some aspects, the techniques described herein relate to an apparatus including: memory cells (e.g., 207, 602, 814, 1704); and at least one controller (e.g. 124) configured to: perform first programming (e.g., initial programming of block 2001) of each memory cell; after the first programming, measure at least one respective first output current from each memory cell by applying a fixed bias to a gate of the memory cell; and perform, based on the respective first output current, second programming (e.g., additional programming of block 2005) of each memory cell until a second output current obtained from the respective memory cell when the fixed bias is applied to the gate of the memory cell corresponds to a stored weight.

In one example, transistor 1030 from pillar 1006 and transistor 1040 from pillar 1008 together provide the memory cell as a single memory cell storing a single weight. This single memory cell provides a total output current that is accumulated on a bitline. The total output current corresponds to the stored weight. In some embodiments, the total output current includes two component currents. A first current is provided by transistor 1030, and a second current is provided by transistor 1040.

In some aspects, the techniques described herein relate to an apparatus, wherein at least one of the first programming or the second programming includes applying one or more voltage pulses to the memory cell.

In some aspects, the techniques described herein relate to an apparatus, wherein the controller is further configured to, after programming the memory cells, perform multiplication by summing output currents from the memory cells, wherein the fixed bias is applied to the gate of each memory cell to provide the summed output currents.

In some aspects, the techniques described herein relate to an apparatus, wherein a wordline (e.g., tier 1612, 1812) is coupled to the gate of each memory cell, and the fixed bias is applied using the wordline.

In some aspects, the techniques described herein relate to an apparatus, further including select transistors (e.g., 1808) that couple each memory cell to a common line (e.g., bitline 1806) that accumulates output currents from the memory cells when performing multiplication, wherein an input signal for the multiplication is provided to gates of the select transistors.

In some aspects, the techniques described herein relate to an apparatus, wherein each memory cell is programmed to one of a plurality of states, each state corresponding to a value of a weight stored in the memory cell.

In some aspects, the techniques described herein relate to an apparatus, wherein each state corresponds to a target output current from the memory cell (e.g., store a 3 bit value represented by 8 states ranging from 000 for a lowest target output current to 111 for a highest target output current).

In some aspects, the techniques described herein relate to an apparatus, wherein a zero state corresponds to a lowest one of the target output currents.

In some aspects, the techniques described herein relate to an apparatus, wherein each memory cell is a NAND memory cell.

In some aspects, the techniques described herein relate to an apparatus, wherein the memory cells are organized in horizontal tiers (e.g., 1608, 1610, 1612) of memory cells, and wherein the tiers are stacked above a semiconductor substrate.

In some aspects, the techniques described herein relate to an apparatus, wherein the controller is further configured to: provide at least one input signal (e.g., inputs provided to gates of select devices 1808) to the memory cells, wherein the input signal is to be multiplied by weights stored by the memory cells, and the memory cells provide output currents based on the input signal; and determine a result based on summing the output currents from the memory cells.

In some aspects, the techniques described herein relate to an apparatus, further including a common line (e.g., bitline) and accumulation circuitry (e.g., 410, 804), wherein: the common line is coupled to receive output currents from the memory cells; and the accumulation circuitry is coupled to the common line and configured to accumulate the output currents.

In some aspects, the techniques described herein relate to an apparatus, further including an interface operable for a host to write data into the memory cells and to read data from the memory cells.

In some aspects, the techniques described herein relate to an apparatus, wherein the weight stored by each memory cell corresponds to a plurality of bits representing a number, the apparatus further including: sensing circuitry (e.g., 150) configured to measure the respective second output current from each memory cell during programming, wherein each memory cell is programmed so that the respective second output current corresponds to the number represented by the plurality of bits stored by the respective memory cell.

In some aspects, the techniques described herein relate to an apparatus, wherein a magnitude of the respective second output current for each of the memory cells programmed to store a non-zero value is a base unit of current (e.g., 35 nA steps) multiplied by the number represented by the bits stored in the respective memory cell.

In some aspects, the techniques described herein relate to an apparatus, wherein the memory cells are configured in vertical pillars of a memory cell array, each pillar including a string of transistors coupled to a bitline for accumulating output currents from the memory cells during matrix vector multiplication (MVM).

In some aspects, the techniques described herein relate to an apparatus, wherein each memory cell is configured using transistors of one or more pillars, and the memory cells selected for performing a multiplication are in a horizontal tier of the memory cell array.

In some aspects, the techniques described herein relate to an apparatus, wherein the weight stored by each memory cell is defined by a state of one or more transistors of the memory cell (e.g., a memory cell having four transistors).

In some aspects, the techniques described herein relate to an apparatus, wherein the state of each transistor in the memory cell is determined by a conductance or a threshold of the transistor.

In some aspects, the techniques described herein relate to a method including: forming logic circuitry on a semiconductor substrate; forming a memory cell array above the semiconductor substrate, the memory cell array including first memory cells configured in pillars extending vertically above the semiconductor substrate; forming a conductive layer above the pillars; and patterning the conductive layer to provide bitlines that are electrically connected to the pillars; wherein the logic circuitry is configured to program the first memory cells by measuring output currents when applying a fixed gate bias to the first memory cells.

In some aspects, the techniques described herein relate to a method, wherein the logic circuitry is further configured to determine an accumulation result for a multiplication by measuring a sum of the output currents from a first bitline when applying the fixed gate bias to the first memory cells.

In some aspects, the techniques described herein relate to a method, further including forming voltage drivers on the semiconductor substrate, the voltage drivers configured to apply the fixed gate bias.

In some aspects, the techniques described herein relate to an apparatus including: a host interface configured to communicate with a host; and logic circuitry configured to: receive, via the host interface from the host, first weights for a neural network; and program first memory cells to store the first weights by measuring output currents when applying a fixed gate bias to the first memory cells.

In some aspects, the techniques described herein relate to an apparatus, wherein the first memory cells are resistive random access memory (RRAM) cells, phase-change memory (PCM) cells, NOR flash memory cells, or NAND flash memory cells.

In some aspects, the techniques described herein relate to an apparatus, further including sensing circuitry configured to measure output currents from the first memory cells.

Integrated circuit devices 101 (e.g., as in FIG. 1) can be configured as a storage device, a memory module, or a hybrid of a storage device and memory module. Examples of a storage device include a solid-state drive (SSD), a flash drive, a universal serial bus (USB) flash drive, an embedded multi-media controller (eMMC) drive, a universal flash storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory module (NVDIMM).

The integrated circuit devices 101 (e.g., as in FIG. 1) can be installed in a computing system as a memory sub-system having an embedded image sensor and an inference computation capability. Such a computing system can be a computing device such as a desktop computer, a laptop computer, a network server, a mobile device, a portion of a vehicle (e.g., airplane, drone, train, automobile, or other conveyance), an internet of things (IoT) enabled device, an embedded computer (e.g., one included in a vehicle, industrial equipment, or a networked commercial device), or such a computing device that includes memory and a processing device.

In general, a computing system can include a host system that is coupled to one or more memory sub-systems (e.g., integrated circuit device 101 of FIG. 1). In one example, a host system is coupled to one memory sub-system.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

For example, the host system can include a processor chipset (e.g., processing device) and a software stack executed by the processor chipset. The processor chipset can include one or more cores, one or more caches, a memory controller (e.g., NVDIMM controller), and a storage protocol controller (e.g., PCIe controller, SATA controller). The host system uses the memory sub-system, for example, to write data to the memory sub-system and read data from the memory sub-system.

The host system can be coupled to the memory sub-system via a physical host interface. Examples of a physical host interface include, but are not limited to, a serial advanced technology attachment (SATA) interface, a peripheral component interconnect express (PCIe) interface, a universal serial bus (USB) interface, a fibre channel, a serial attached SCSI (SAS) interface, a double data rate (DDR) memory bus interface, a small computer system interface (SCSI), a dual in-line memory module (DIMM) interface (e.g., DIMM socket interface that supports double data rate (DDR)), an open NAND flash interface (ONFI), a double data rate (DDR) interface, a low power double data rate (LPDDR) interface, a compute express link (CXL) interface, or any other interface. The physical host interface can be used to transmit data between the host system and the memory sub-system. The host system can further utilize an NVM express (NVMe) interface to access components (e.g., memory devices) when the memory sub-system is coupled with the host system by the PCIe interface. The physical host interface can provide an interface for passing control, address, data, and other signals between the memory sub-system and the host system. In general, the host system can access multiple memory sub-systems via a same communication connection, multiple separate communication connections, or a combination of communication connections.

The processing device of the host system can be, for example, a microprocessor, a central processing unit (CPU), a processing core of a processor, an execution unit, etc. In some instances, the controller can be referred to as a memory controller, a memory management unit, or an initiator. In one example, the controller controls the communications over a bus coupled between the host system and the memory sub-system. In general, the controller can send commands or requests to the memory sub-system for desired access to memory devices. The controller can further include interface circuitry to communicate with the memory sub-system. The interface circuitry can convert responses received from the memory sub-system into information for the host system.

The controller of the host system can communicate with a controller of the memory sub-system to perform operations such as reading data, writing data, or erasing data at the memory devices, and other such operations. In some instances, the controller is integrated within the same package of the processing device. In other instances, the controller is separate from the package of the processing device. The controller or the processing device can include hardware such as one or more integrated circuits (ICs), discrete components, a buffer memory, or a cache memory, or a combination thereof. The controller or the processing device can be a microcontroller, special-purpose logic circuitry (e.g., a field programmable gate array (FPGA), an application specific integrated circuit (ASIC), etc.), or another suitable processor.

The memory devices can include any combination of the different types of non-volatile memory components and volatile memory components. The volatile memory devices can be, but are not limited to, random access memory (RAM), such as dynamic random access memory (DRAM) and synchronous dynamic random access memory (SDRAM).

Some examples of non-volatile memory components include a negative-and (or, NOT AND) (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices can include one or more arrays of memory cells such as SLCs, MLCs, TLCs, QLCs, PLCs, or any combination of such. In some embodiments, a particular memory device can include an SLC portion, an MLC portion, a TLC portion, a QLC portion, or a PLC portion of memory cells, or any combination thereof. The memory cells of the memory devices can be grouped as pages that can refer to a logical unit of the memory device used to store data. With some types of memory (e.g., NAND), pages can be grouped to form blocks.

Although non-volatile memory devices such as 3D cross-point type and NAND type memory (e.g., 2D NAND, 3D NAND) are described, the memory device can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), spin transfer torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory sub-system controller (or controller for simplicity) can communicate with the memory devices to perform operations such as reading data, writing data, or erasing data at the memory devices and other such operations (e.g., in response to commands scheduled on a command bus by controller). The controller can include hardware such as one or more integrated circuits (ICs), discrete components, or a buffer memory, or a combination thereof. The hardware can include digital circuitry with dedicated (i.e., hard-coded) logic to perform the operations described herein. The controller can be a microcontroller, special-purpose logic circuitry (e.g., a field programmable gate array (FPGA), an application specific integrated circuit (ASIC), etc.), or another suitable processor.

The controller can include a processing device (processor) configured to execute instructions stored in a local memory. In the illustrated example, the local memory of the controller includes an embedded memory configured to store instructions for performing various processes, operations, logic flows, and routines that control operation of the memory sub-system, including handling communications between the memory sub-system and the host system.

In some embodiments, the local memory can include memory registers storing memory pointers, fetched data, etc. The local memory can also include read-only memory (ROM) for storing micro-code. While the example memory sub-system includes a controller, in another embodiment of the present disclosure, a memory sub-system does not include a controller, and can instead rely upon external control (e.g., provided by an external host, or by a processor or controller separate from the memory sub-system).

In general, the controller can receive commands or operations from the host system and can convert the commands or operations into instructions or appropriate commands to achieve the desired access to the memory devices. The controller can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices. The controller can further include host interface circuitry to communicate with the host system via the physical host interface. The host interface circuitry can convert the commands received from the host system into command instructions to access the memory devices as well as convert responses associated with the memory devices into information for the host system.

The memory sub-system can also include additional circuitry or components that are not illustrated. In some embodiments, the memory sub-system can include a cache or buffer (e.g., DRAM) and address circuitry (e.g., a row decoder and a column decoder) that can receive an address from the controller and decode the address to access the memory devices.

In some embodiments, the memory devices include local media controllers that operate in conjunction with memory sub-system controller to execute operations on one or more memory cells of the memory devices. An external controller (e.g., memory sub-system controller) can externally manage the memory device (e.g., perform media management operations on the memory device). In some embodiments, a memory device is a managed memory device, which is a raw memory device combined with a local media controller for media management within the same memory device package. An example of a managed memory device is a managed NAND (MNAND) device.

The controller or a memory device can include a storage manager configured to implement storage functions discussed above. In some embodiments, the controller in the memory sub-system includes at least a portion of the storage manager. In other embodiments, or in combination, the controller or the processing device in the host system includes at least a portion of the storage manager. For example, the controller, or the processing device can include logic circuitry implementing the storage manager. For example, the controller, or the processing device (processor) of the host system, can be configured to execute instructions stored in memory for performing the operations of the storage manager described herein. In some embodiments, the storage manager is implemented in an integrated circuit chip disposed in the memory sub-system. In other embodiments, the storage manager can be part of the firmware of the memory sub-system, an operating system of the host system, a device driver, or an application, or any combination therein.

In one embodiment, an example machine of a computer system within which a set of instructions, for causing the machine to perform any one or more of the methods discussed herein, can be executed. In some embodiments, the computer system can correspond to a host system that includes, is coupled to, or utilizes a memory sub-system or can be used to perform the operations described above. In alternative embodiments, the machine can be connected (e.g., networked) to other machines in a LAN, an intranet, an extranet, or the internet, or any combination thereof. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a personal digital assistant (PDA), a cellular telephone, a web appliance, a server, a network router, a switch or bridge, a network-attached storage facility, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system includes a processing device, a main memory (e.g., read-only memory (ROM), flash memory, dynamic random access memory (DRAM) such as synchronous DRAM (SDRAM) or Rambus DRAM (RDRAM), static random access memory (SRAM), etc.), and a data storage system, which communicate with each other via a bus (which can include multiple buses).

A processing device can be one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. A processing device can also be one or more special-purpose processing devices such as an application specific integrated circuit (ASIC), a field programmable gate array (FPGA), a digital signal processor (DSP), network processor, or the like. The processing device is configured to execute instructions for performing the operations and steps discussed herein. The computer system can further include a network interface device to communicate over the network.

The data storage system can include a machine-readable medium (also known as a computer-readable medium) on which is stored one or more sets of instructions or software embodying any one or more of the methodologies or functions described herein. The instructions can also reside, completely or at least partially, within the main memory and within the processing device during execution thereof by the computer system, the main memory and the processing device also constituting machine-readable storage media. The machine-readable medium, data storage system, or main memory can correspond to the memory sub-system.

In one embodiment, the instructions include instructions to implement functionality corresponding to the operations described above. While the machine-readable medium is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to convey the substance of their work most effectively to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

In one embodiment, a memory device includes a controller that controls voltage drivers (e.g., 203, 213, 223 of FIG. 2) and/or other components of the memory device. The controller is instructed by firmware or other software. The software can be stored on a machine-readable medium as instructions, which can be used to program the controller. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In this description, various functions and operations may be described as being performed by or caused by computer instructions to simplify description. However, those skilled in the art will recognize what is meant by such expressions is that the functions result from execution of the computer instructions by one or more controllers or processors, such as a microprocessor. Alternatively, or in combination, the functions and operations can be implemented using special-purpose circuitry, with or without software instructions, such as using application-specific integrated circuit (ASIC) or field-programmable gate array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

1. An apparatus comprising:
memory cells; and
at least one controller configured to:
perform first programming of each memory cell;
after the first programming, measure at least one respective first output current from each memory cell by applying a fixed bias to a gate of the memory cell; and
perform, based on the respective first output current, second programming of each memory cell until a second output current obtained from the respective memory cell when the fixed bias is applied to the gate of the memory cell corresponds to a stored weight.

2. The apparatus of claim 1, wherein at least one of the first programming or the second programming comprises applying one or more voltage pulses to the memory cell.

3. The apparatus of claim 1, wherein the controller is further configured to, after programming the memory cells, perform multiplication by summing third output currents from the memory cells, wherein the fixed bias is applied to the gate of each memory cell to provide the third output currents.

4. The apparatus of claim 1, wherein a wordline is coupled to the gate of each memory cell, and the fixed bias is applied using the wordline.

5. The apparatus of claim 1, further comprising select transistors that couple each memory cell to a common line that accumulates third output currents from the memory cells when performing multiplication, wherein an input signal for the multiplication is provided to gates of the select transistors.

6. The apparatus of claim 1, wherein each memory cell is programmed to one of a plurality of states, each state corresponding to a value of a weight stored in the memory cell.

7. The apparatus of claim 6, wherein each state corresponds to a target output current from the memory cell.

8. The apparatus of claim 7, wherein a zero state corresponds to a lowest one of the target output currents.

9. The apparatus of claim 1, wherein each memory cell is a NAND memory cell.

10. The apparatus of claim 1, wherein the memory cells are organized in horizontal tiers of memory cells, and wherein the tiers are stacked above a semiconductor substrate.

11. The apparatus of claim 1, wherein the controller is further configured to:
provide at least one input signal to the memory cells, wherein the input signal is to be multiplied by weights stored by the memory cells, and the memory cells provide third output currents based on the input signal; and
determine a result based on summing the third output currents from the memory cells.

12. The apparatus of claim 1, further comprising a common line and accumulation circuitry, wherein:
the common line is coupled to receive third output currents from the memory cells; and
the accumulation circuitry is coupled to the common line and configured to accumulate the third output currents.

13. The apparatus of claim 1, further comprising an interface operable for a host to write data into the memory cells and to read data from the memory cells.

14. The apparatus of claim 1, wherein the weight stored by each memory cell corresponds to a plurality of bits representing a number, the apparatus further comprising:
sensing circuitry configured to measure the respective second output current from each memory cell during programming, wherein each memory cell is programmed so that the respective second output current corresponds to the number represented by the plurality of bits stored by the respective memory cell.

15. The apparatus of claim 14, wherein a magnitude of the respective second output current for each of the memory cells programmed to store a non-zero value is a base unit of current multiplied by the number represented by the bits stored in the respective memory cell.

16. The apparatus of claim 1, wherein the memory cells are configured in vertical pillars of a memory cell array, each pillar including a string of transistors coupled to a bitline for accumulating output currents from the memory cells during matrix vector multiplication (MVM).

17. The apparatus of claim 16, wherein each memory cell is configured using transistors of one or more pillars, and the memory cells selected for performing a multiplication are in a horizontal tier of the memory cell array.

18. The apparatus of claim 1, wherein the weight stored by each memory cell is defined by a state of one or more transistors of the memory cell.

19. The apparatus of claim 18, wherein the state of each transistor in the memory cell is determined by a conductance or a threshold of the transistor.

20. A method comprising:
forming logic circuitry on a semiconductor substrate;
forming a memory cell array above the semiconductor substrate, the memory cell array including first memory cells configured in pillars extending vertically above the semiconductor substrate;
forming a conductive layer above the pillars; and
patterning the conductive layer to provide bitlines that are electrically connected to the pillars;
wherein the logic circuitry is configured to program the first memory cells by measuring output currents when applying a fixed gate bias to the first memory cells.

21. The method of claim 20, wherein the logic circuitry is further configured to determine an accumulation result for a multiplication by measuring a sum of the output currents from a first bitline when applying the fixed gate bias to the first memory cells.

22. The method of claim 20, further comprising forming voltage drivers on the semiconductor substrate, the voltage drivers configured to apply the fixed gate bias.

23. An apparatus comprising:
a host interface configured to communicate with a host; and
logic circuitry configured to:
receive, via the host interface from the host, first weights for a neural network; and
program first memory cells to store the first weights by measuring output currents when applying a fixed gate bias to the first memory cells.

24. The apparatus of claim 23, wherein the first memory cells are resistive random access memory (RRAM) cells, phase-change memory (PCM) cells, NOR flash memory cells, or NAND flash memory cells.

25. The apparatus of claim 23, further comprising sensing circuitry configured to measure output currents from the first memory cells.
